(19) United States
(12) Patent Application Publication
(10) Pub. No.: US 2025/0359122 A1
(43) Pub. Date: Nov. 20, 2025

(54) SEMICONDUCTOR DEVICE WITH DIELECTRIC STRUCTURE IN CHANNEL REGION AND MANUFACTURING METHODS THEREOF

(71) Applicant: Taiwan Semiconductor Manufacturing Company, Ltd., Hsin-Chu (TW)

(72) Inventors: Jung-Chien Cheng, Tainan City (TW); Guan-Lin Chen, Hsinchu County (TW); Shi Ning Ju, Hsinchu City (TW); Kuo-Cheng Chiang, Zhubei City (TW); Chih-Hao Wang, Hsinchu County (TW)

(21) Appl. No.: 19/284,372

(22) Filed: Jul. 29, 2025

Related U.S. Application Data
(63) Continuation of application No. 18/764,936, filed on Jul. 5, 2024.
(60) Provisional application No. 63/620,225, filed on Jan. 12, 2024.

(51) Int. Cl. H10D 30/43; H10D 30/01; H10D 30/62; H10D 30/67; H10D 62/10; H10D 64/01

(52) U.S. Cl. CPC H10D 30/43; H10D 30/014; H10D 30/6215; H10D 30/6735; H10D 30/6757; H10D 62/115; H10D 62/121; H10D 64/018; H10D 64/021; H10D 64/017

(57) ABSTRACT

The present disclosure provides a semiconductor device and a method of forming the same. The semiconductor device includes an isolation feature disposed on a substrate, a fin-shape base protruding from the substrate and through the isolation feature, nanostructures disposed over a top surface of the fin-shape base, a dielectric structure disposed over a topmost one of the nanostructures, a gate structure wrapping around at least one of the nanostructures, the gate structure interfacing with a bottom surface of the dielectric structure, a gate spacer extending along a sidewall of the gate structure, and an epitaxial feature abutting the nanostructures. The bottom surface of the dielectric structure is below a top surface of the gate structure.

### PRIORITY DATA

This is a continuation application of U.S. patent application Ser. No. 18/764,936, filed Jul. 5, 2024, which claims benefit of U.S. Provisional Patent Application No. 63/620,225, filed Jan. 12, 2024, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend around a channel region to provide access to the channel region on all four sides.

To improve the performance of GAA transistors, efforts are being invested in developing structures in the channel regions that improve the uniformity of metal gate heights and channel member thicknesses. While conventional channel region structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1A and 1B illustrate a flowchart of an example method for making a semiconductor device in accordance with some embodiments of the present disclosure.

FIGS. 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, and 33A illustrate perspective views of a semiconductor device constructed according to the method in FIGS. 1A and 1B, in accordance with some embodiments.

FIGS. 2B, 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B, 32B, and 33B illustrate cross-sectional views in a Y-Z plane of a portion of the semiconductor device in respective perspective views during fabrication processes according to the method of FIGS. 1A and 1B, in accordance with some embodiments of the present disclosure.

FIGS. 2C, 3C, 4C, 5C, 6C, 7C, 8C, 9C, 10C, 11C, 12C, 13C, 14C, 15C, 16C, 17C, 18C, 19C, 20C, 21C, 22C, 23C, 24C, 25C, 26C, 27C, 28C, 29C, 30C, 31C, 32C, and 33C illustrate cross-sectional views in an X-Z plane of a portion of the semiconductor device in respective perspective views during fabrication processes according to the method of FIGS. 1A and 1B, in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure provides a semiconductor device with a dielectric structure suspended above vertically stacked semiconductor nanostructures in a channel region of a gate-all-around (GAA) transistor.

The channel region of a GAA transistor may be disposed in semiconductor nanostructures (also referred to as channel members), such as nanowire channel members, bar-shaped channel members, nanosheet channel members, column-shaped channel members, post-shaped channel members, and/or other suitable channel configurations. Depending on the shapes of the channel members, a GAA transistor may also be referred to as a nanowire transistor or a nanosheet transistor. Despite of the shapes, each of the channel members of a GAA transistor extends between and is coupled to two epitaxial features in two opposing source/drain regions. The epitaxial features are also referred to as source/drain features or source/drain epitaxial features. Source/drain region(s) may refer to a source or a drain, individually or collectively dependent upon the context. During a replacement gate process, a dummy gate stack is removed to form a gate trench exposing channel layers, the channel layers are subsequently released by removing interleaving sacrificial layers to become channel members, a metal gate structure is subsequently deposited above and between the channel members to wrap around the channel members, and then a planarization process, such as a chemical mechanical planarization (CMP) process, is performed to recess the metal gate structure. During the removal of the dummy gate stack, the topmost one of the channel layers may suffer from some etching loss from above due to limited etching contrast. Accordingly, the topmost one of the channel members may become thinner than other channel members underneath, which introduces channel member thickness inconsistency. The process variation during the planarization of the metal gate structures may also introduce metal gate height inconsistency.

The present disclosure provides embodiments of a semiconductor device where a dielectric structure is provided above the stack of channel members in the channel region. The dielectric structure may be formed from a hard mask layer in some embodiments. This additional dielectric structure in the channel region provides etching protection during the removal of the dummy gate stack. The dielectric structure also functions as a planarization stop layer to define a uniform top surface of the metal gate structures during the metal gate planarization process. Thus, the uniformity of the metal gate heights and the channel member thicknesses are both improved.

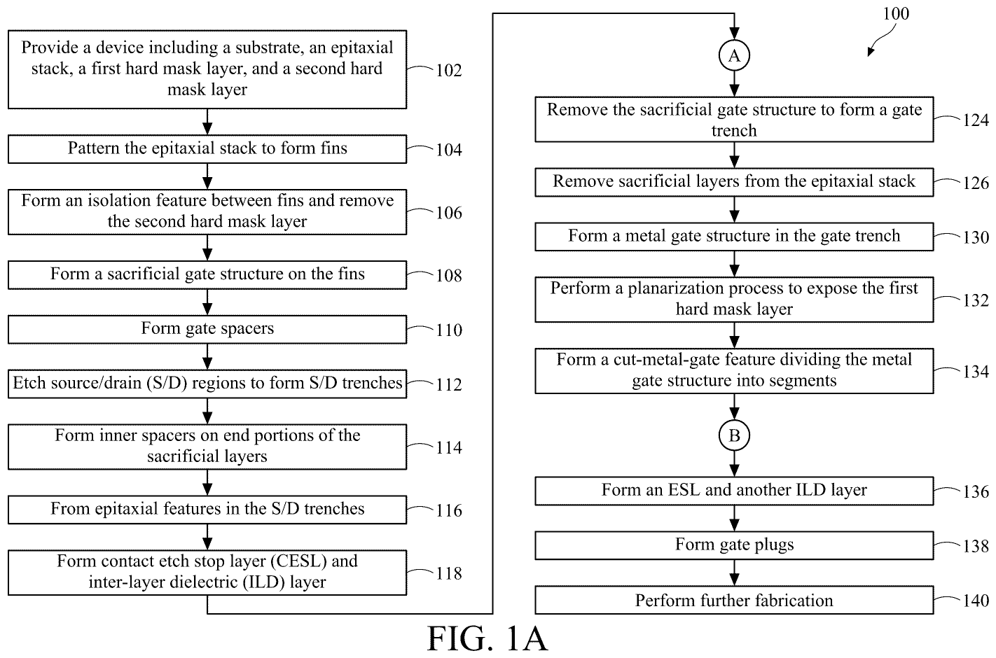

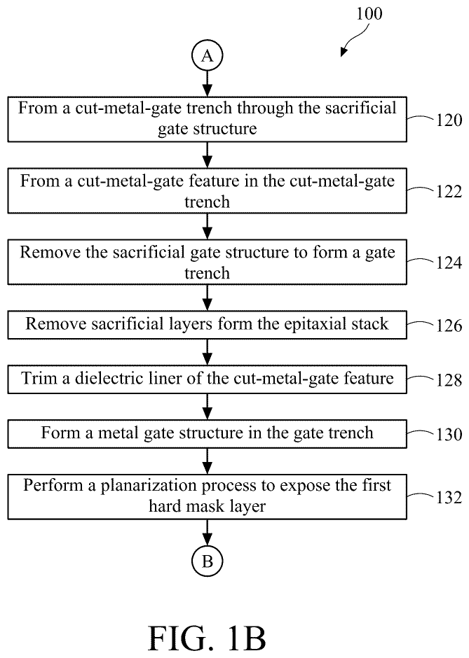

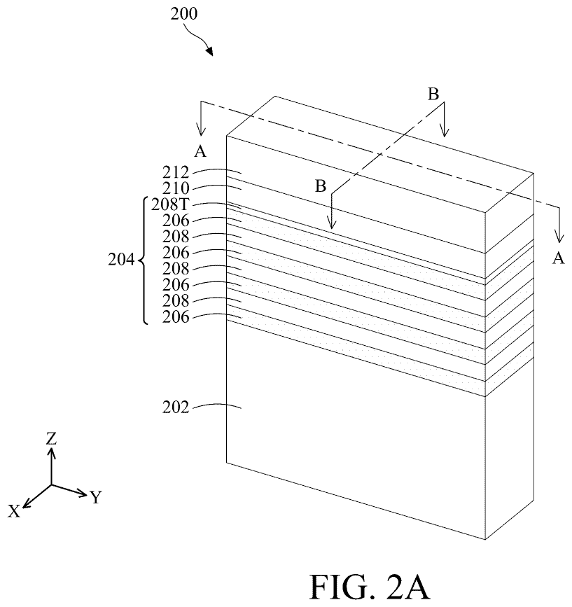

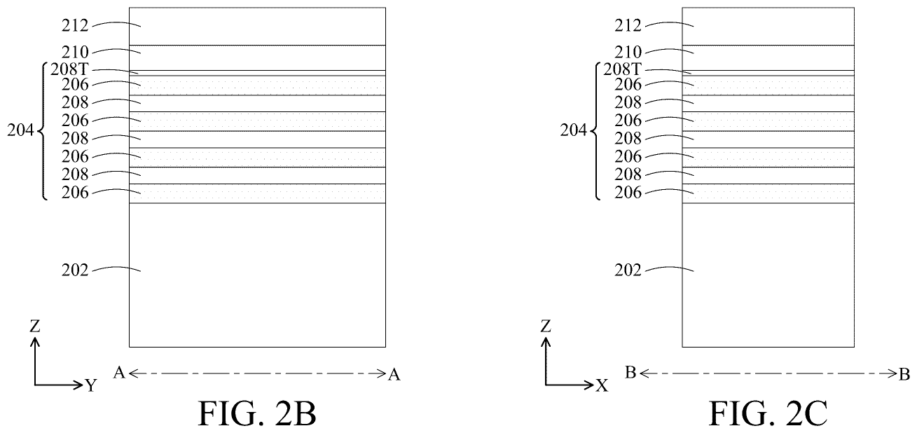

FIG. 1A illustrates a flow chart of a method 100 for fabricating a semiconductor device according to various embodiments of the present disclosure. FIG. 1B illustrates an alternative embodiment of the method 100. Additional processing is contemplated by the present disclosure. Additional operations can be provided before, during, and after method 100, and some of the operations described can be moved, replaced, or eliminated for additional embodiments of method 100. FIGS. 1A and 1B are described below in conjunction with FIGS. 2A through 33C that illustrate various perspective and cross-sectional views of a semiconductor device (or device) 200 at various steps of fabrication according to the method 100, in accordance with some embodiments. In some embodiments, the device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. FIGS. 2A through 33C have been simplified for the sake of clarity to better understand the inventive concepts of the present disclosure. Additional features can be added in the device 200, and some of the features described below can be replaced, modified, or eliminated in other embodiments of the device 200.

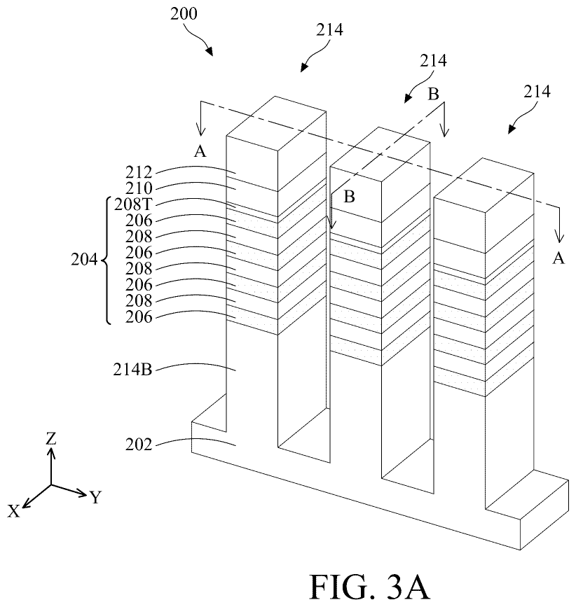

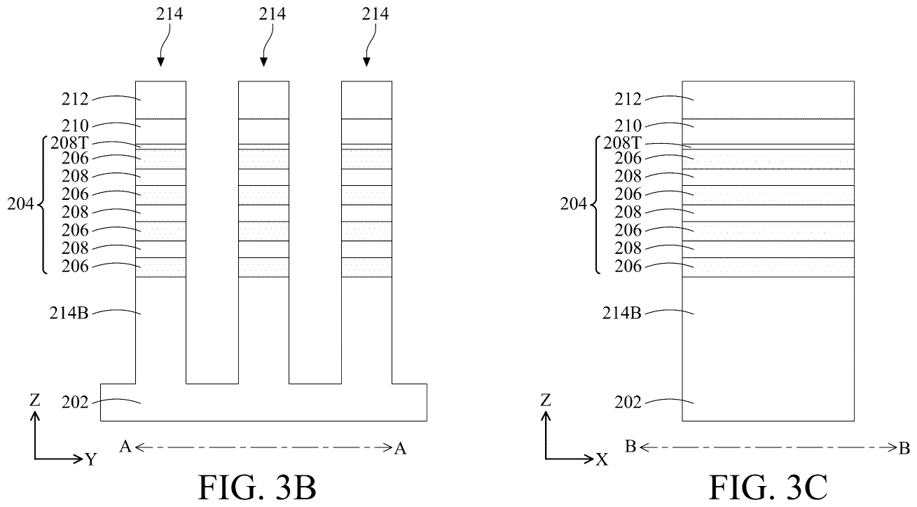

At operation 102, the method 100 (FIG. 1A) provides a device 200 having a substrate 202, a stack 204 disposed on the substrate 202, a first hard mask layer 210 disposed on the stack 204, and a second hard mask layer 212 disposed on the first hard mask layer 210, as shown in FIGS. 2A-2C. FIG. 2A illustrates a perspective view of the device 200, and FIGS. 2B and 2C illustrate cross-sectional views of the device 200, in portion, along the A-A line and the B-B line in FIG. 2A, respectively. Particularly, the A-A line is a cut along the lengthwise direction of to-be-formed gate structures (direction “Y” or Y-direction) and the B-B line is a cut along the lengthwise direction of to-be-formed channel members (direction “X” or X-direction). The A-A lines and B-B lines in FIGS. 3A through 31C are similarly configured.

In some embodiments, the substrate 202 is a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the n-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). It is noted that four (4) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 1 and 20.

In some embodiments, all sacrificial layers 206 may have a substantially uniform first thickness between about 3 nm and about 10 nm, and all of the channel layers 208 may have a substantially uniform second thickness between about 3 nm and about 8 nm. The first thickness and the second thickness may be the same or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

In the depicted embodiment, the stack 204 further includes a top sacrificial layer 208T disposed on the topmost one of the sacrificial layers 206. In some instances, compositions of the channel layers 208 and the top sacrificial layer 208T are substantially the same, such as silicon (Si). The top sacrificial layer 208T functions to protect the stack 204 from damages during fabrication processes. The top sacrificial layer 208T may be thinner than either of the channel layers 208 and the sacrificial layers 206. In some instances, a thickness of the top sacrificial layer 208T may be between about 1 nm and about 2 nm.

The semiconductor layers in the stack 204 may be deposited using a molecular beam epitaxy (MBE) process, a vapor phase deposition (VPE) process, and/or other suitable epitaxial growth processes. Therefore, the stack 204 is also referred to as the epitaxial stack 204, and the layers 206 and 208 are also referred to as the epitaxial layers 206 and 208. As stated above, in at least some examples, the sacrificial layers 206 include an epitaxially grown silicon germanium (SiGe) layer, the channel layers 208 include an epitaxially grown silicon (Si) layer, and the top sacrificial layer 208T includes an epitaxially grown silicon (Si) layer. In some embodiments, the sacrificial layers 206, the channel layers 208, and the top sacrificial layer 208T are substantially dopant-free, where for example, no intentional doping is performed during the epitaxial growth processes for the stack 204. In some implementations, the top surface of the substrate 202 is in a (100) crystalline plane, and accordingly each layer of the stack 204 has a (100) top surface. In some alternative implementations, the top surface of the substrate is in a (110) crystalline plane, and accordingly each layer of the stack 204 has a (110) top surface.

Still referring to FIGS. 2A-2C, the first hard mask layer 210 may include metal oxides, silicon nitride (SiN), silicon carbonitride (SiCN), silicon oxycarbide (SiOC), silicon oxycarbonitride (SiOCN), or a low-k dielectric material. The metal oxides may include aluminum oxide, zirconium oxide, tantalum oxide, yttrium oxide, titanium oxide, lanthanum oxide, or other suitable metal oxide. While not explicitly shown, the first hard mask layer 210 may be a single layer or a multilayer, such as a bi-layer structure with two different material compositions. In some implementations, the first hard mask layer 210 may be deposited using chemical vapor deposition (CVD), including low pressure CVD (LPCVD) and plasma enhanced CVD (PECVD), physical vapor deposition (PVD), atomic layer deposition (ALD), or other suitable process. As described in further detail below, the first hard mask layer 210 will be patterned into a dielectric feature suspended above channel members in the channel region for protecting topmost channel member from etching loss and improving metal gate height uniformity by also functioning as a planarization stop layer. In some embodiments, the first hard mask layer 210 has a thickness ranging from about 2 nm to about 20 nm. This range is not arbitrary or trivial. If the thickness is less than about 2 nm, the resultant dielectric feature would be too thin to effectively function as a planarization stop layer; if the thickness is more than about 20 nm, the remaining portion of the dielectric feature in the final structure would be too thick that increases a metal gate height, which consequently leads to an increased parasitic capacitance that may slow down circuit speed.

The second hard mask layer 212 is deposited on the first hard mask layer 210. In some implementations, the second hard mask layer 212 may be deposited using CVD, LPCVD, PECVD, PVD, ALD, or other suitable methods. The second hard mask layer 212 may be a single layer or a multilayer. When the second hard mask layer 212 is a multilayer, the second hard mask layer 212 may include a pad oxide layer and a pad nitride layer. The pad oxide layer may be made of silicon oxide, and the pad nitride layer may be made of silicon nitride. In various embodiments, the first hard mask layer 210 and the second hard mask layer 212 include different material compositions, which allows the second hard mask layer 212 to be removed in a selective etching process with no (or minimal) etching loss occurred to the first hard mask layer 210. In some embodiments, the second hard mask layer 212 has a thickness ranging from about 2 nm to about 20 nm. In furtherance of some embodiments, a thickness of the second hard mask layer 212 is larger than a thickness of the first hard mask layer 210. Alternatively, a thickness of the second hard mask layer 212 may be smaller than a thickness of the first hard mask layer 210.

At operation 104, the method 100 (FIG. 1A) patterns the stack 204 to form semiconductor fins 214 (also referred to as fins 214), as shown in FIGS. 3A-3C. The fins 214 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. The second hard mask layer 212 is patterned into a mask pattern. Through openings defined in the patterned second hard mask layer 212, the etching process forms trenches extending sequentially through the first hard mask layer 210, the stack 204, and a top portion of the substrate 202. The trenches define the fins 214. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fins 214 by etching the stack 204 and a top portion of the substrate 202. The patterned top portion of the substrate 202 is also denoted as a fin-shape base 214B. The fin-shape base 214B may still be considered as a top part of the substrate 202 as the context requires. In the depicted embodiment, the fins 214, which includes the patterned stack 204 and the fin-shape base 214B, extends vertically along the Z direction and lengthwise along the X-direction. In some instances, the fins 214 measures between about 6 nm and about 80 nm wide along the Y-direction, and a distance between opposing sidewalls of two adjacent fins 214 measures between about 6 nm and about 115 nm along the Y-direction. In FIGS. 3A-3C, three (3) fins 214 are spaced apart along the Y-direction. But the number of the fins 214 is not limited to three, and may be as small as one, two, or more than three.

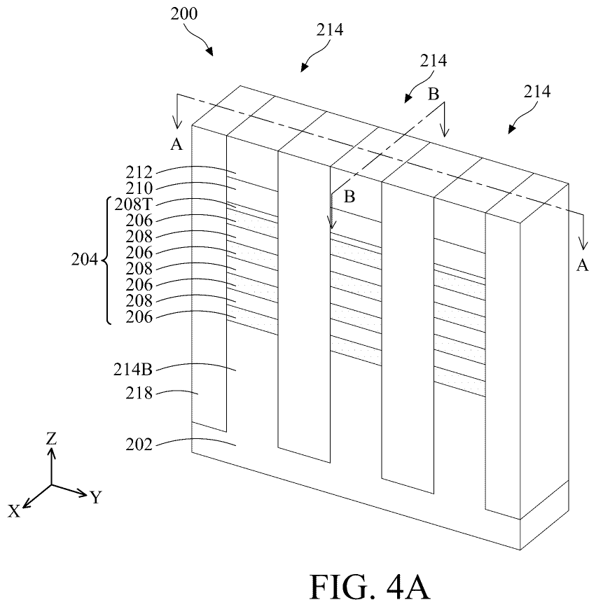

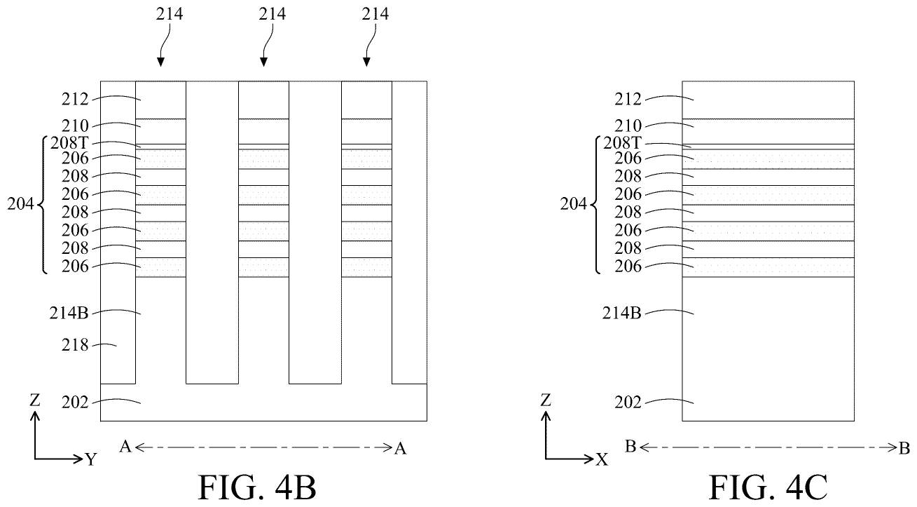

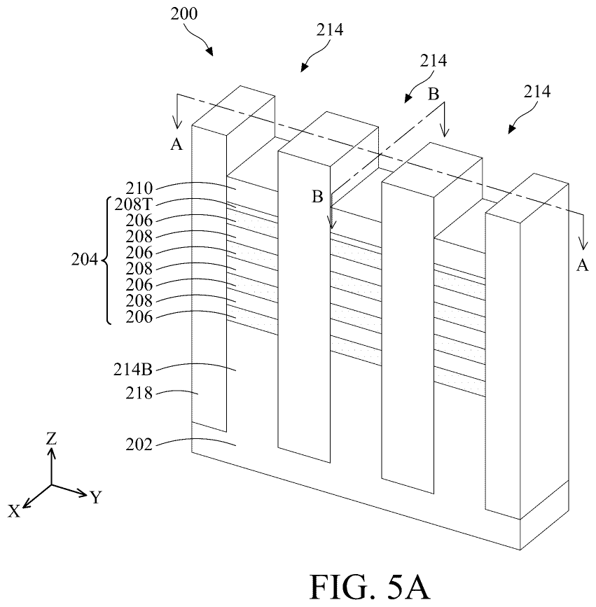

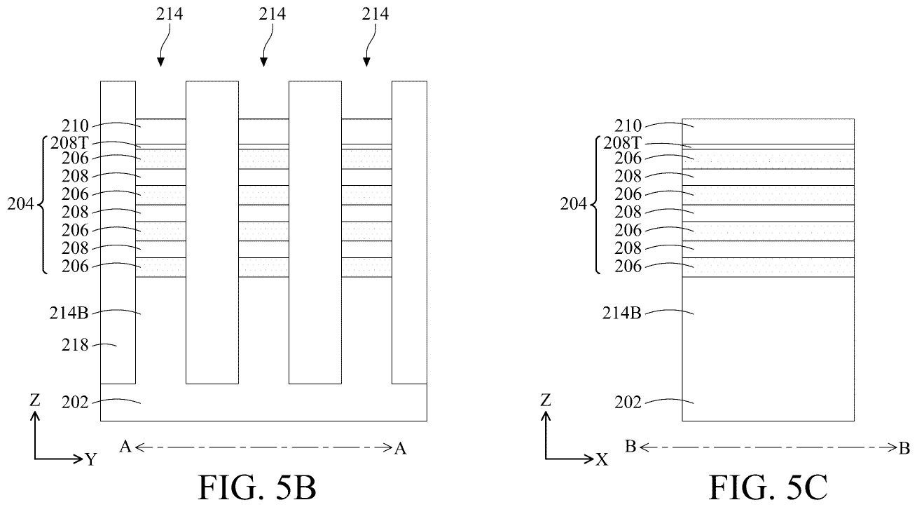

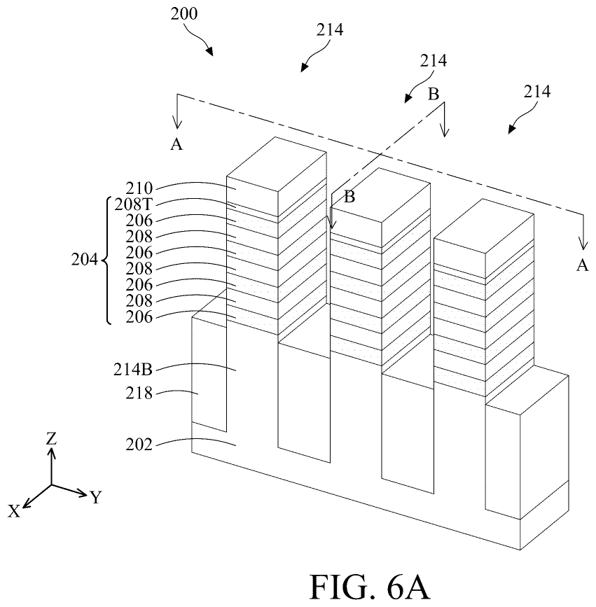

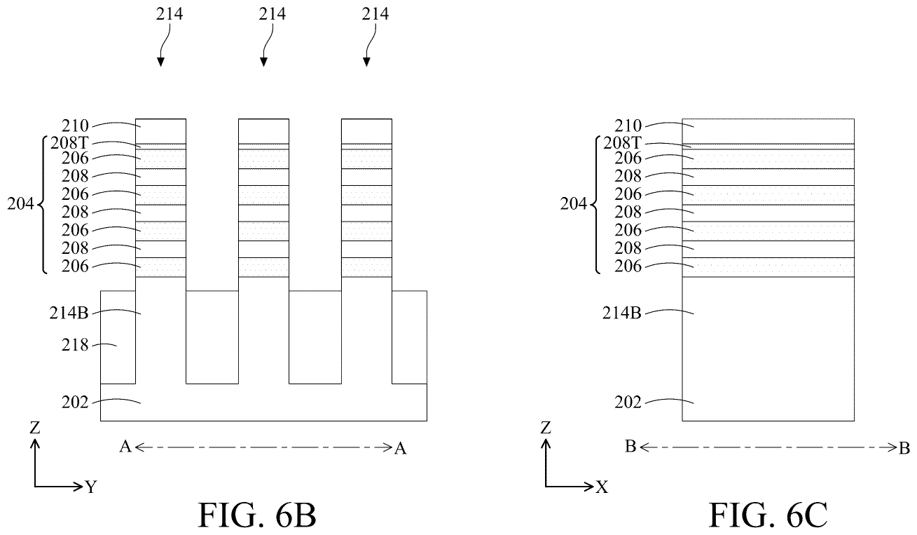

At operation 106, the method 100 (FIG. 1A) deposits a dielectric material in the trenches between adjacent fins 214 to form an isolation feature 218, as shown in FIGS. 4A-4C, 5A-5C, and 6A-6C. The isolation feature 218 may include one or more dielectric layers. Suitable dielectric materials for the isolation feature 218 may include silicon oxides, silicon nitrides, silicon carbides, fluorosilicate glass (FSG), low-k dielectric materials, and/or other suitable dielectric materials. The dielectric material may be deposited by any suitable technique including thermal growth, CVD, HDP-CVD, PVD, ALD, and/or spin-on techniques. Then, a planarization operation, such as a CMP process, is performed to expose a top surface of the second hard mask layer 212, as shown in FIGS. 4A-4C. Subsequently, a selective etching process is performed to remove the second hard mask layer 212, as shown in FIGS. 5A-5C. The selective etching process is tuned to be selective to the material(s) in the patterned second hard mask layer 212, and the patterned first hard mask layer 210 and the isolation feature 218 remain substantially intact. After the patterned first hard mask layer 210 is exposed, the isolation feature 218 is recessed to form shallow trench isolation (STI) feature (also denoted as STI feature 218 thereafter). Any suitable etching technique may be used to recess the isolation features 218 including dry etching, wet etching, RIE, and/or other etching methods, and in an exemplary embodiment, an anisotropic dry etching is used to selectively remove the dielectric material of the isolation feature 218 without etching the fins 214 (including the first hard mask layer 210), as shown in FIGS. 6A-6C. In the depicted embodiment, the top surface of the STI feature 218 may be below the bottom surface of the stack 204. Alternatively, the top surface of the STI feature 218 may be coplanar with the bottom surface of the stack 204, in accordance with some other embodiments. At the conclusion of operation 106, since the patterned second hard mask layer 212 has been removed and the patterned first hard mask layer 210 still remains, the patterned first hard mask layer 210 may also be simply referred to as hard mask feature (or just “hard mask”) 210, dielectric feature 210, dielectric structure 210, or dielectric nanostructure 210.

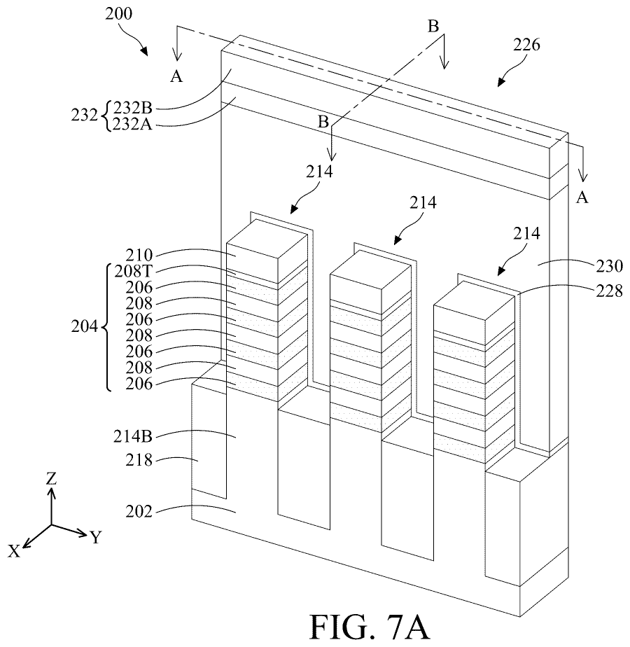

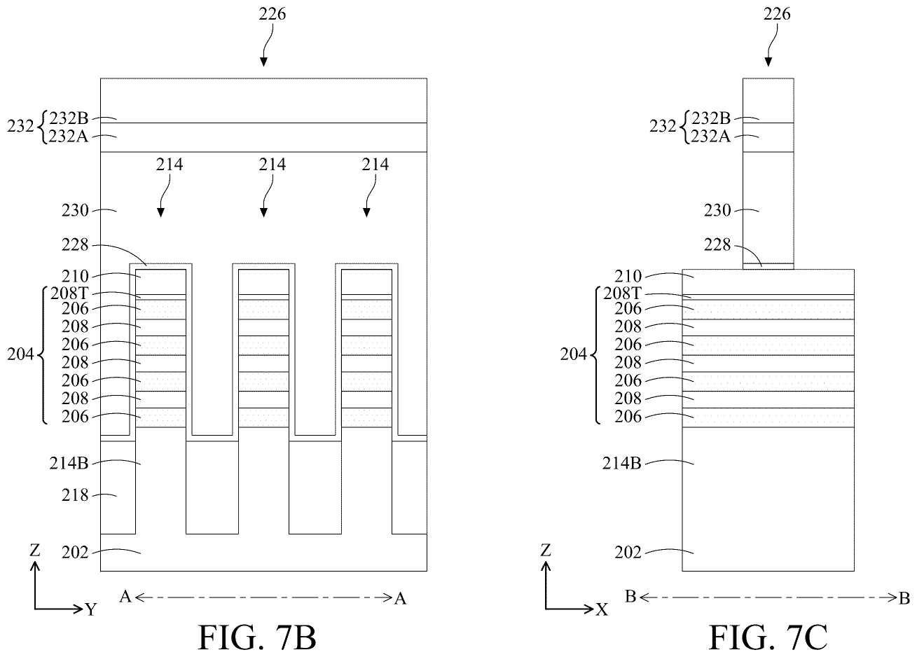

At operation 108, the method 100 (FIG. 1A) forms a sacrificial (dummy) gate structure 226, as shown in FIGS. 7A-7C. In the illustrated embodiment, one sacrificial gate structure 226 is shown, but the number of the sacrificial gate structures 226 is not limited to one, two, or more sacrificial gate structures, which are arranged in the X-direction. The sacrificial gate structure 226 is formed over portions of the fins 214 which are to be channel regions. The sacrificial gate structure 226 defines channel regions of the to-be-formed transistors. The sacrificial gate structure 226 includes a sacrificial gate dielectric layer 228 and a sacrificial gate electrode layer 230. The sacrificial gate structure 226 is formed by first blanket depositing the sacrificial gate dielectric layer 228 over the fins 214. A sacrificial gate electrode layer 230 is then deposited on the sacrificial gate dielectric layer 228 and over the fins 214. The sacrificial gate electrode layer 230 includes silicon such as polycrystalline silicon or amorphous silicon. In some embodiments, the sacrificial gate electrode layer 230 is subjected to a planarization operation. The sacrificial gate dielectric layer 228 and the sacrificial gate electrode layer 230 may be deposited using CVD, including LPCVD and PECVD, PVD, ALD, or other suitable process. Subsequently, a mask layer 232 is formed over the sacrificial gate electrode layer 230. The mask layer 232 may include a pad silicon oxide layer 232A and a silicon nitride mask layer 232B. Subsequently, a patterning operation is performed on the mask layer 232 and sacrificial gate dielectric and electrode layers are patterned into the sacrificial gate structure 226. By patterning the sacrificial gate structure 226, the fins 214 are partially exposed on opposite sides of the sacrificial gate structure 226, thereby defining source/drain (S/D) regions.

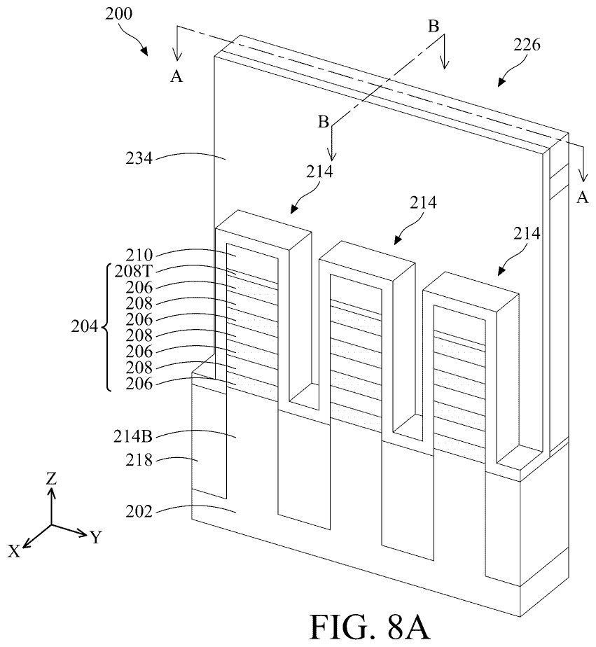

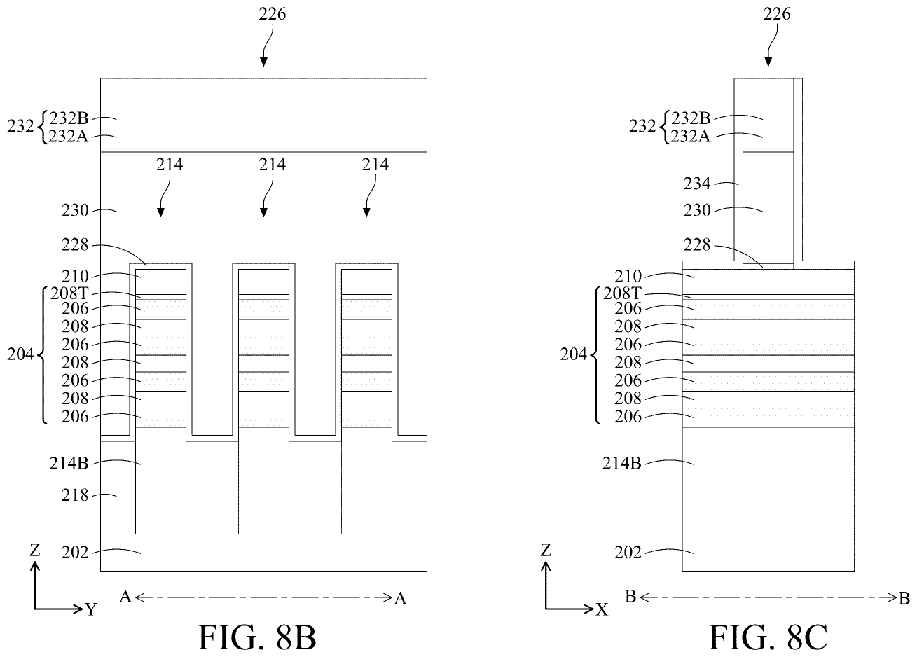

At operation 110, the method 100 (FIG. 1A) forms gate spacers 234 on sidewalls of the sacrificial gate structure 226, as well as on sidewalls of the fins 214, as shown in FIGS. 8A-8C. The gate spacers 234 may include a dielectric material such as silicon oxide, silicon nitride, silicon carbide, silicon oxynitride, SiCN, silicon oxycarbide, SiOCN, and/or combinations thereof. In some embodiments, the gate spacers 234 include multiple layers, such as main spacer walls, liner layers, and the like. By way of example, the gate spacers 234 may be formed by blanket depositing a dielectric material layer in a conformal manner over the sacrificial gate structure 226 using processes such as, a CVD process, a subatmospheric CVD (SACVD) process, a flowable CVD process, an ALD process, a PVD process, or other suitable process. The gate spacers 234 may be a single layer or a multilayer. In one embodiment, the gate spacers 234 include a first layer and a second layer disposed over the first layer. The first layer may include silicon oxynitride and the second layer may include silicon nitride. In some instances, the gate spacers 234 measure between about 3 nm and about 8 nm thick along the X-direction.

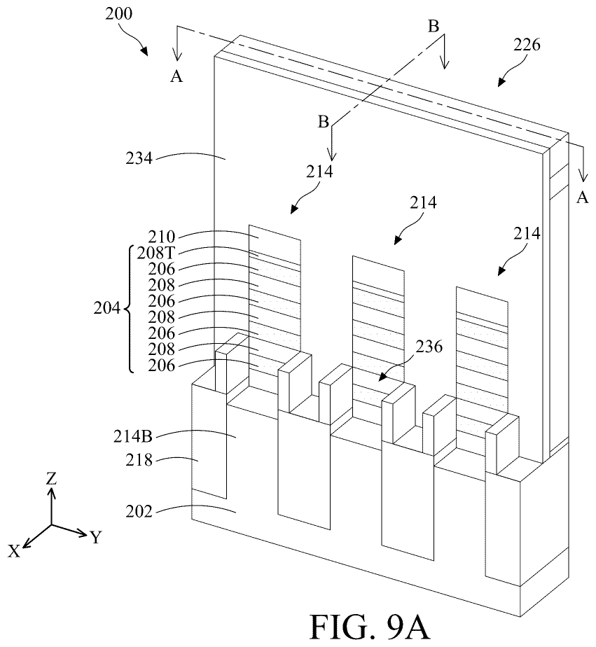

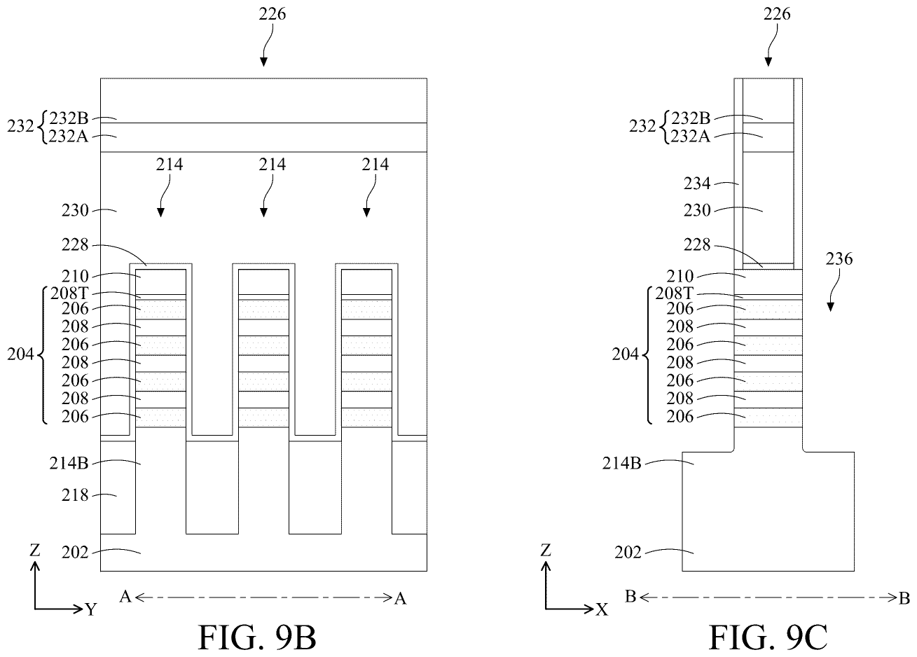

At operation 112, the method 100 (FIG. 1A) recesses portions of the fins 214 to form S/D trenches (or S/D recesses) 236 in the S/D regions, as shown in FIGS. 9A-9C. The stacked epitaxial layers 206 and 208 and the hard mask 210 are etched down in the S/D regions. In many embodiments, operation 112 forms the S/D trenches 236 by a suitable etching process, such as a dry etching process, a wet etching process, or an RIE process. The etching process at operation 112 may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof. The etchant is selected such that a top portion of the fin-shape base 214B is also recessed, and a top portion of the sidewalls of the STI feature 218 is exposed in the S/D trenches 236. In the depicted embodiment, a portion of the gate spacers 234 previously deposited on sidewalls of the fins 214 remains in the S/D regions at the conclusion of operation 112, which is also referred to as fin spacers or source/drain spacers.

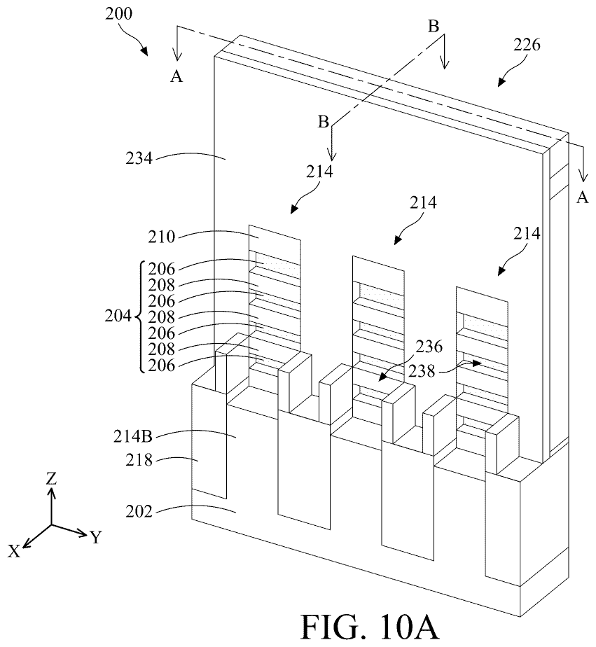

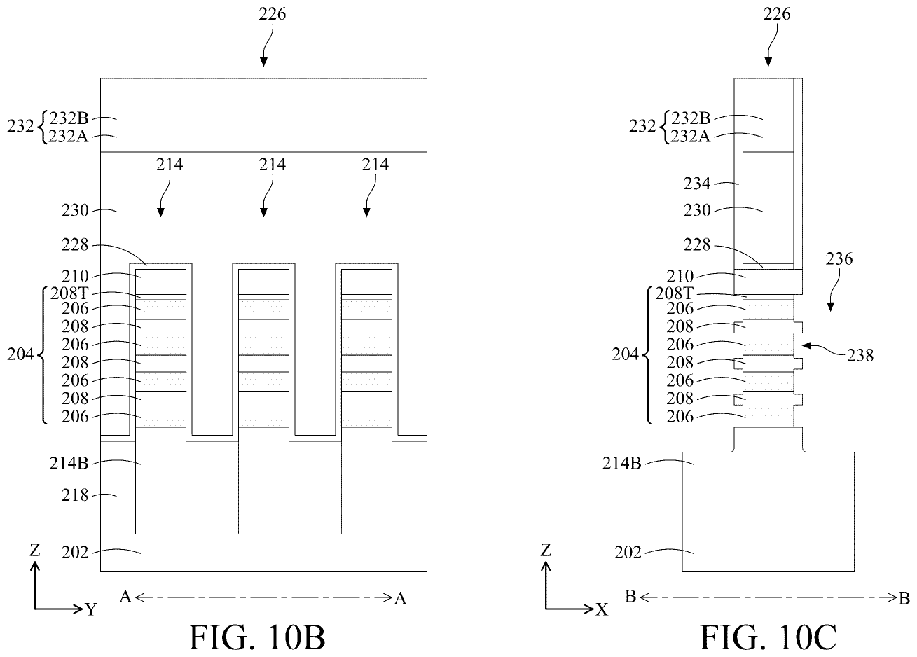

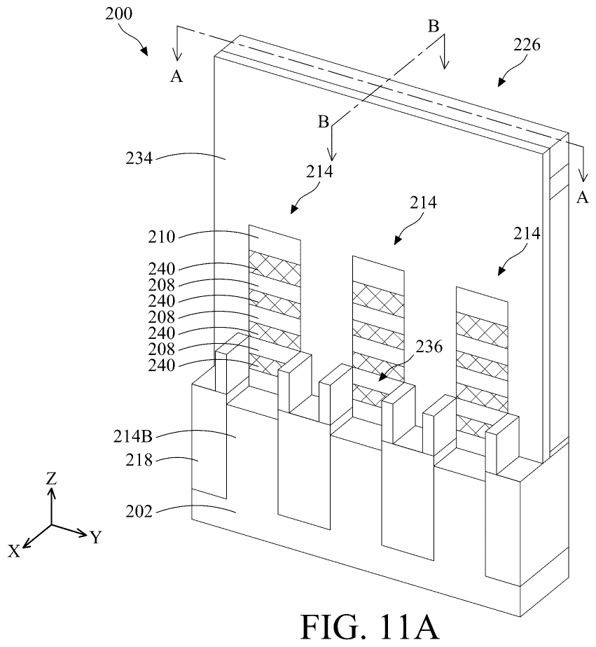

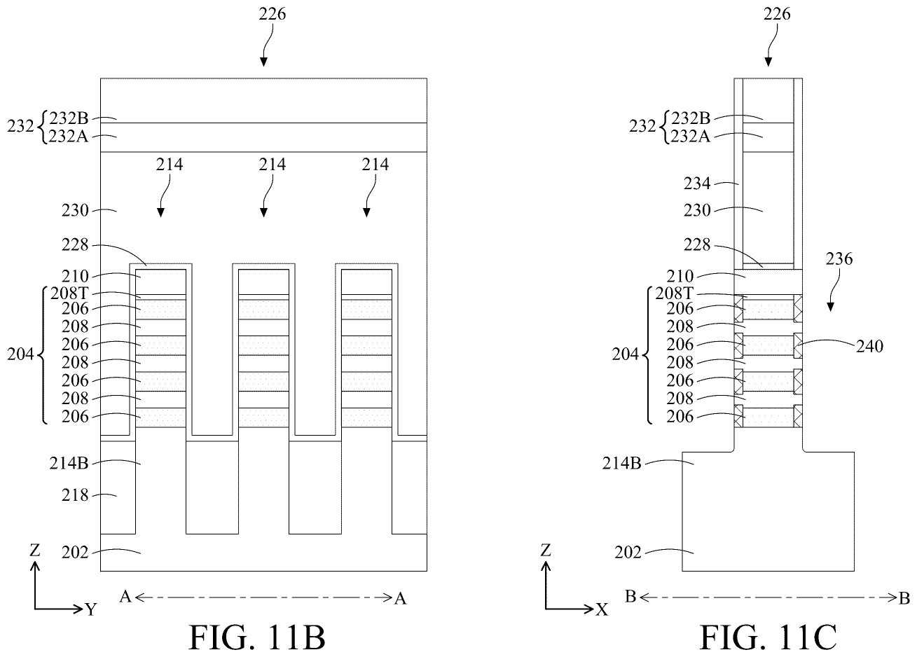

At operation 114, the method 100 (FIG. 1A) forms inner spacers 240 abutting end portions of the sacrificial layers 206, as shown in FIGS. 10A-10C and 11A-11C. Operation 114 may first laterally etch the end portions of the epitaxial layers 206, thereby forming cavities 238 to be filled by a dielectric material as the inner spacers 240, as shown in FIGS. 10A-10C. The sacrificial layers 206 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, operation 114 may first selectively oxidize lateral ends of the sacrificial layers 206 that are exposed in the S/D trenches 236 to increase the etch selectivity between the epitaxial layers 206 and 208. In some examples, the oxidation process may be performed by exposing the device 200 to a wet oxidation process, a dry oxidation process, or a combination thereof. The cavities 238 also exposes end portions of the channel layers 208 and the top sacrificial layer 208T. Due to the limited etching selectivity, the end portions of the channel layers 208 and the top sacrificial layer 208T may suffer some etching loss. For example, the end portions of the channel layers 208 may become thinner in the Z-direction than the center portions, and the end portions of the top sacrificial layer 208T may be recessed in the X-direction such that a bottom surface of the hard mask 210 is exposed in the cavities 238, as depicted in FIG. 10C. Next, operation 114 forms inner spacers 240 on the recessed lateral ends of the upper epitaxial layers 206, as shown in FIGS. 11A-11C. By way of example, operation 114 may include blanket depositing an inner spacer material layer in the S/D trenches 236. Particularly, the inner spacer material layer is deposited on the recessed lateral ends of the upper sacrificial layers 206 exposed in the cavities 238. The inner spacer material layer may include silicon nitride (SiN), silicon carbonitride (SiCN), silicon oxycarbide (SiOC), silicon oxycarbonitride (SiOCN), or other suitable dielectric materials. In some embodiments, the inner spacer material layer includes the same material composition as in the hard masks 210. In some embodiments, the inner spacer material layer includes a different material composition from the hard masks 210. In some embodiments, the inner spacer material layer is deposited as a conformal layer with substantially uniform thickness on different surfaces. The inner spacer material layer can be formed by ALD or any other suitable method. By conformally forming the inner spacer material layer, a volume of the cavities is reduced or completely filled. After the inner spacer material layer is deposited, an etching operation is performed to partially remove the inner spacer material layer from the S/D trenches 236. Particularly, the inner spacer material layer is removed from the sidewalls of the sacrificial layers 216. By this etching, the inner spacer material layer remains substantially within the cavities, because of a small volume of the cavities. Generally, plasma dry etching etches a layer in wide and flat areas faster than a layer in concave (e.g., holes, grooves and/or slits) portions. Thus, the inner spacer material layer can remain inside the cavities 238. The remaining portions of the inner spacer material layer inside the cavities provides isolation between to-be-formed metal gate structures and to-be-formed S/D epitaxial features, which are referred to as the inner spacers 240.

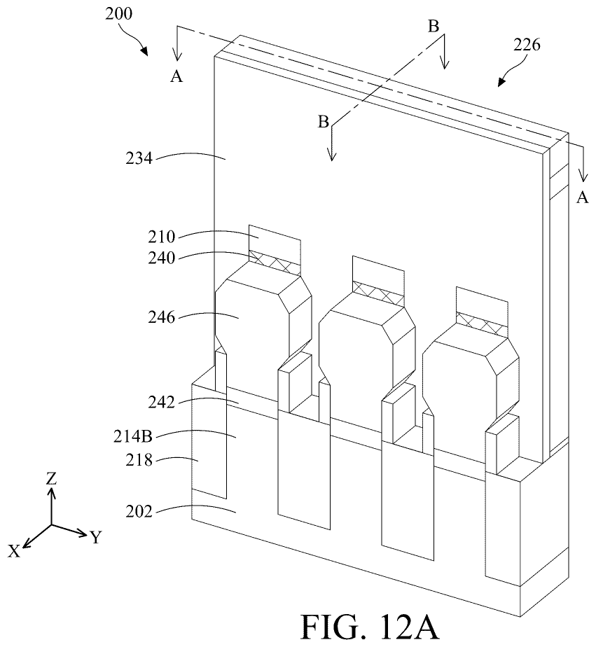

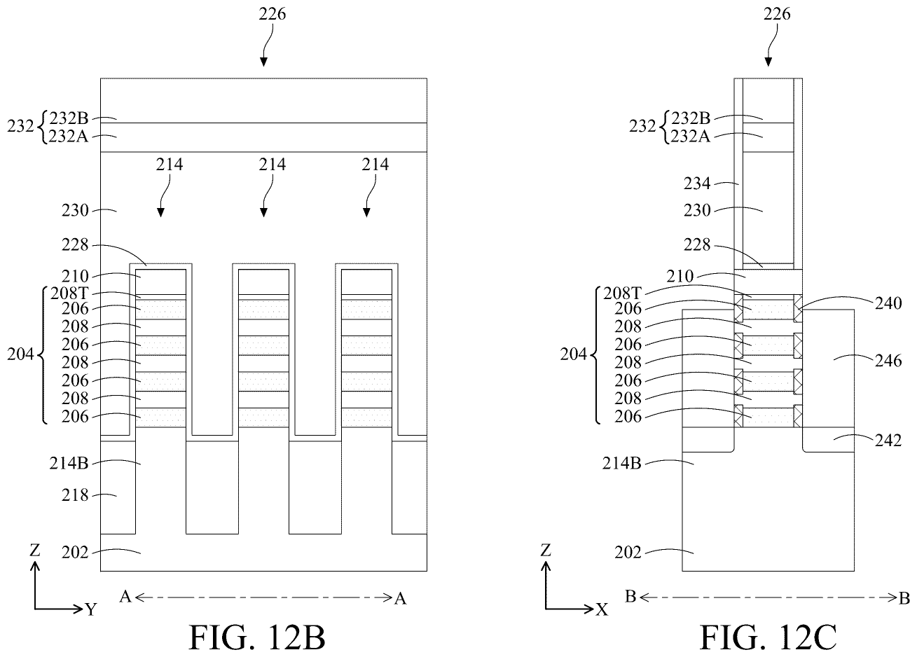

At operation 116, the method 100 (FIG. 1A) forms epitaxial features in the S/D trenches 236, such as a buffer epitaxial layer 242 and a doped epitaxial layer 246 disposed above the buffer epitaxial layer 242, as shown in FIGS. 12A-12C. The buffer epitaxial layer 242 is deposited in the bottom of the S/D trenches 236. In some embodiments, the buffer epitaxial layer 242 includes the same material as the substrate 202 and the channel layers 208, such as silicon (Si), except for a dopant condition (doping element and/or doping concentration). For example, the buffer epitaxial layer 242 is made of non-doped silicon, the substrate 202 is made of doped silicon, and the channel layers 208 are made of non-doped or doped silicon. In some embodiments, the buffer epitaxial layer 242 includes the same material as the sacrificial layers 206, such as silicon germanium (SiGe), with the germanium (Ge) content the same of different from each other. In some embodiments, the buffer epitaxial layer 242 includes SiₓGe₁₋ₓ, in which x is between about 0.1 and 1. The germanium content range is not trivial. When the germanium content is greater than about 90%, the lattice mismatch between silicon and germanium may cause too much defect at the interface between the buffer epitaxial layer 242 and the substrate 202. In other embodiments, the buffer epitaxial layer 242, the channel layers 208, and the sacrificial layers 206 are made of semiconductor materials different from each other. In various embodiments, the buffer epitaxial layer 242 is dopant-free, where for example, no intentional doping is performed during the epitaxial growth process. As a comparison, in one instance, the substrate 202 is lightly doped (e.g., n-type dopants in p-type regions for forming PFETs or p-type dopant in n-type regions for forming NFETs) and thus has a higher doping concentration than the buffer epitaxial layer 242. The dopant-free buffer epitaxial layer 242 provides a high resistance path from the S/D regions to the substrate 202, such that the leakage current into the substrate 202 is suppressed.

The doped epitaxial layer 246 is formed above the buffer epitaxial layer 242. The channel layers 208 connect two doped epitaxial layers 246 in two opposing source/drain regions. The doped epitaxial layers 246 are also referred to as S/D epitaxial features. In some embodiments, a dielectric film (not shown) may be deposited on the top surface of the buffer epitaxial layer 242 to separate the doped epitaxial layer 246 from contacting the buffer epitaxial layer 242. In other words, the bottom surface of the doped epitaxial layer 246 may rest on the top surface of the dielectric film. The dielectric film further suppresses the leakage current from the source/drain regions. Alternatively, the bottom surface of the doped epitaxial layer 246 may directly rest on the top surface of the buffer epitaxial layer 242, as shown in the depicted embodiment. In some embodiments, the doped epitaxial layer 246 include epitaxially grown semiconductor materials such as epitaxially grown silicon, germanium, or silicon germanium. The doped epitaxial layer 246 can be formed by any epitaxy processes including chemical vapor deposition (CVD) techniques (for example, vapor phase epitaxy and/or Ultra-High Vacuum CVD), molecular beam epitaxy, other suitable epitaxial growth processes, or combinations thereof. The doped epitaxial layer 246 may be doped with n-type dopants and/or p-type dopants. In some embodiments, for n-type transistors, the doped epitaxial layer 246 include silicon and can be doped with carbon, phosphorous, arsenic, other n-type dopant, or combinations thereof (for example, forming Si:C S/D epitaxial features, Si:P S/D epitaxial features, or Si:C:P S/D epitaxial features). In some embodiments, for p-type transistors, the doped epitaxial layer 246 include silicon germanium or germanium, and can be doped with boron, other p-type dopant, or combinations thereof (for example, forming Si:Ge:B S/D epitaxial features). The doped epitaxial layer 246 may include multiple epitaxial semiconductor layers having different levels of dopant density. In some embodiments, annealing processes (e.g., rapid thermal annealing (RTA) and/or laser annealing) are performed to activate dopants in the doped epitaxial layer 246. In the depicted embodiment, the top surface of the doped epitaxial layer 246 is under the bottom surface of the top sacrificial layer 208T. The topmost inner spacer 240 separates the doped epitaxial layer 246 from contacting the top sacrificial layer 208T. The top surface of the doped epitaxial layer 246 intersects the sidewall of the topmost inner spacer 240.

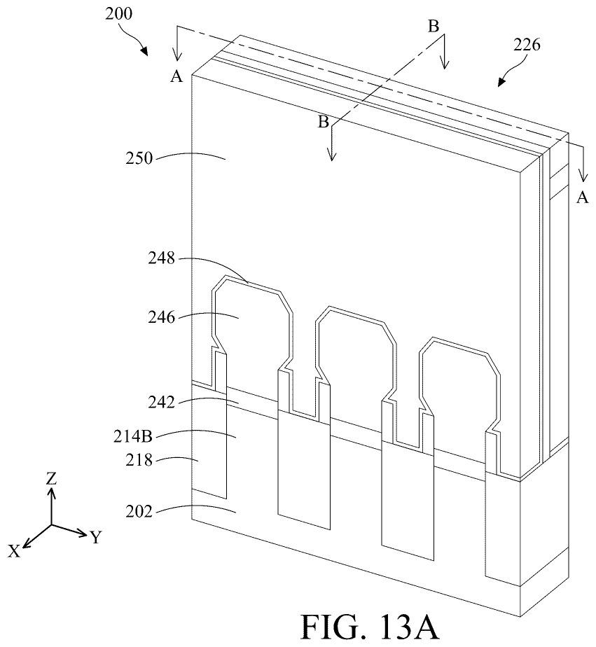

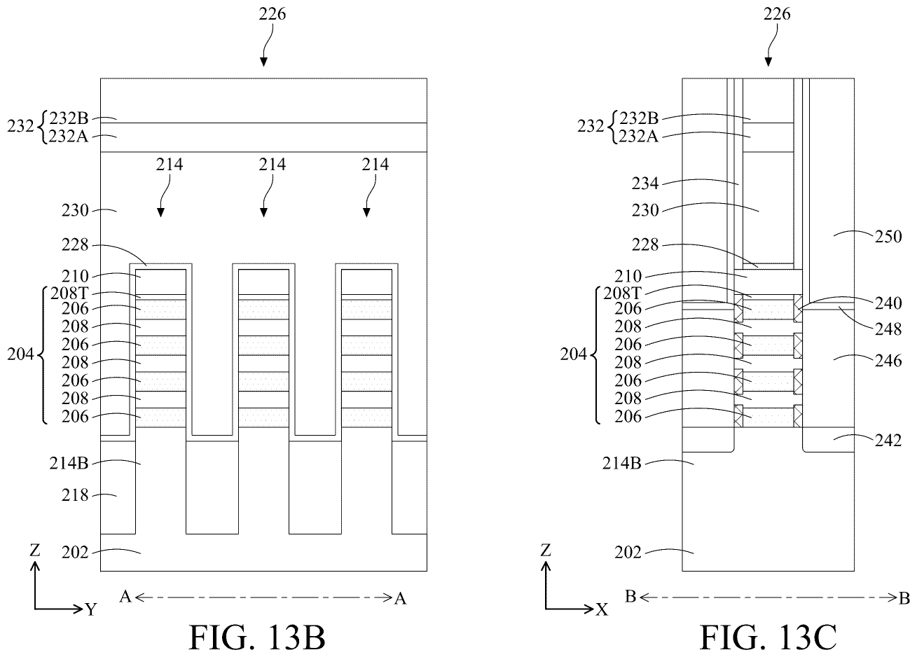

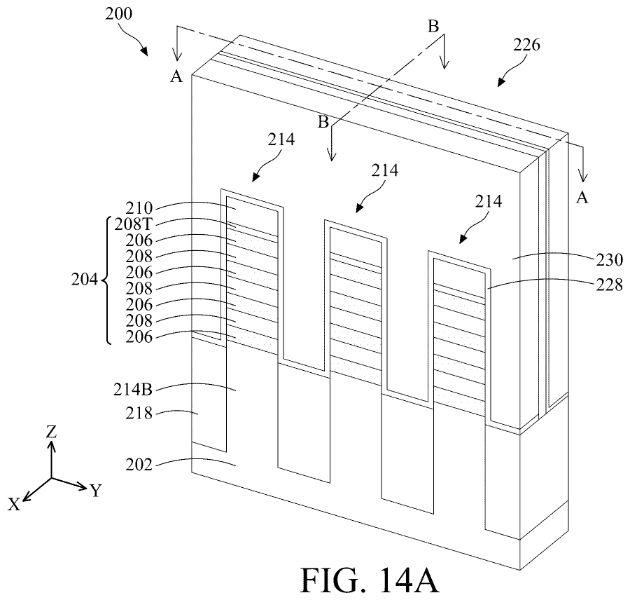

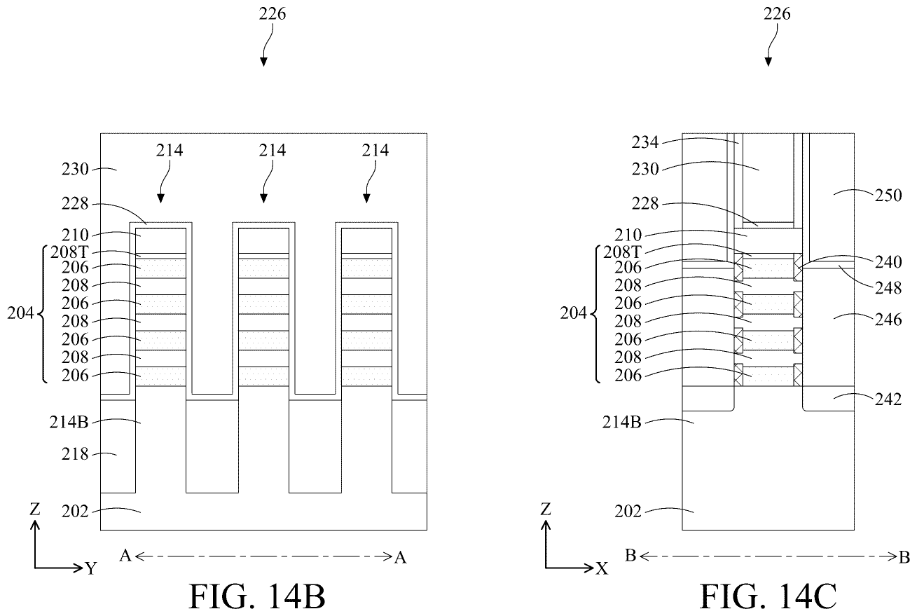

At operation 118, the method 100 (FIG. 1A) forms a contact etch stop layer (CESL) 248 over the doped epitaxial features 246 and an interlayer dielectric (ILD) layer 250 over the CESL layer 248, as shown in FIGS. 13A-13C and 14A-14C. The CESL layer 248 may include silicon nitride, silicon oxynitride, silicon nitride with oxygen (O) or carbon (C) elements, and/or other materials; and may be formed by CVD, PVD (physical vapor deposition), ALD, or other suitable methods. The ILD layer 250 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be formed by PECVD or FCVD (flowable CVD), or other suitable methods. In some embodiments, forming the ILD layer 250 further includes performing a CMP process to planarize a top surface of the device 200, such that the mask layer 232 over top portions of the sacrificial gate structures 226 are removed, as shown in FIGS. 14A-14C. In the depicted embodiment, the CESL 248 and the ILD layer 250 are also disposed on sidewalls of the hard mask 210 and the topmost inner spacer 240, such that the bottom surfaces of the CESL 248 and the ILD layer 250 are below the bottom surface of the top sacrificial layer 208T.

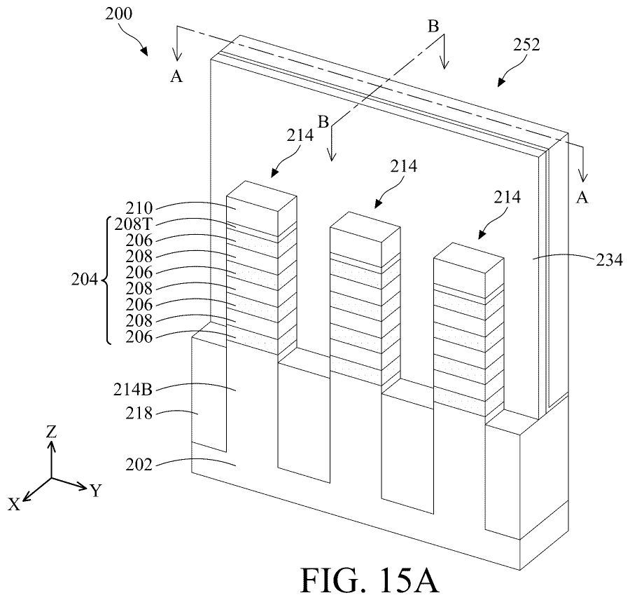

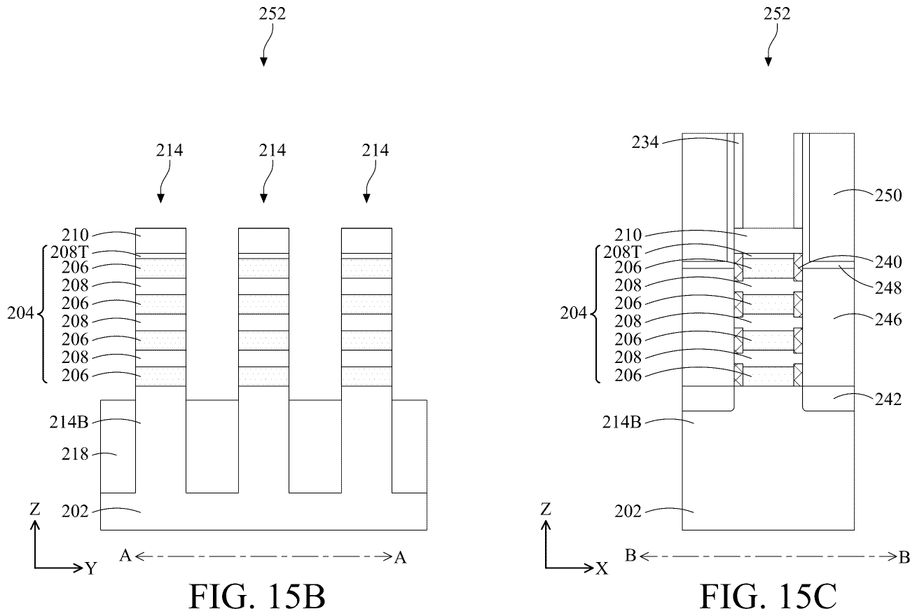

At operation 124, the method 100 (FIG. 1A) removes the sacrificial gate structure 226 to form a gate trench 252 in an etch process, as shown in FIGS. 15A-15C. The removal of the sacrificial gate structure 226 may include one or more etching processes that are selective to the material of the sacrificial gate structure 226. For example, the removal of the sacrificial gate structure 226 may be performed using as a selective wet etch, a selective dry etch, or a combination thereof that is selective to the sacrificial gate structure 226. In one embodiments, the etching process is a reactive-ion etching (RIE). After the removal of the sacrificial gate structure 226, sidewalls of the channel layers 208 and the sacrificial layers 206 in the channel region, as well as the hard masks 210, are exposed in the gate trench 252. In some embodiments that an anisotropic dry etching is applied, the hard masks 210 protect the underneath epitaxial layers 206 and 208 from etching loss. A thickness of the hard masks 210 may reduce about 5% to about 20% at the conclusion of operation 124 due to limited etching contrast.

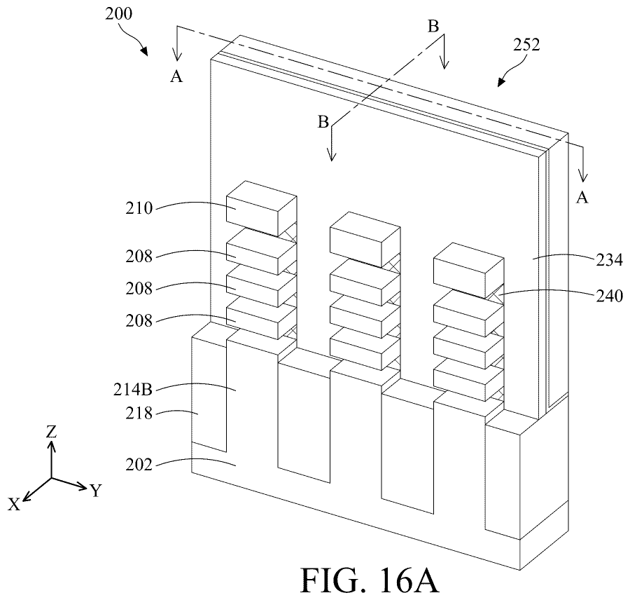

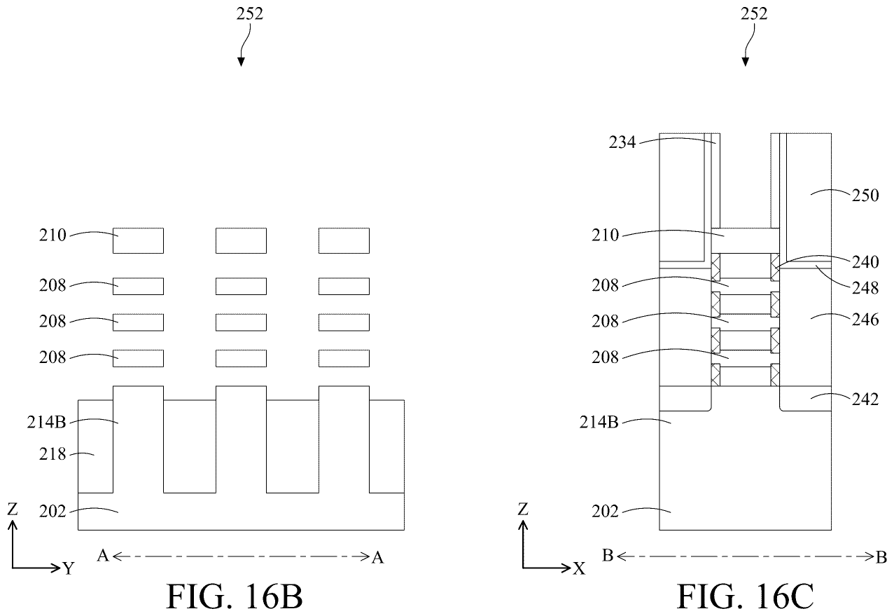

At operation 126, the method 100 (FIG. 1A) selectively removes the sacrificial layers 206 from the gate trench 252 in an etch process, as shown in FIG. 16A-16C. The selective removal of the sacrificial layers 206 releases the channel layers 208 to form channel members (also numbered as 208). The channel members 208 may also be referred to as nanostructures 208 or semiconductor nanostructures 208. Due to the etching protection from the hard mask 210 (or dielectric structure 210), the topmost channel member 208 and the other channel members 208 underneath substantially have the same thickness. The hard mask 210 and the channel members 208 (at least the topmost channel member 208) may have substantially the same width measured in the Y-direction. In the depicted embodiment, a thickness of the hard mask 210 may be larger than a thickness of the channel members 208 at the conclusion of operation 126. Alternatively, a thickness of the hard mask 210 may be equal to or smaller than a thickness of the channel members 208 at the conclusion of operation 126. The selective removal of the sacrificial layers 206 also leaves behind gaps between the channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). The selective removal of the sacrificial layers 206 also removes the top sacrificial layer 208T.

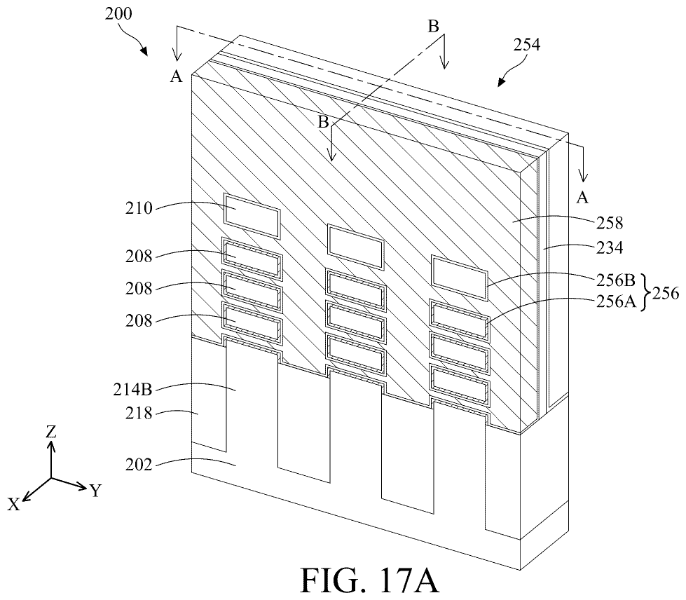

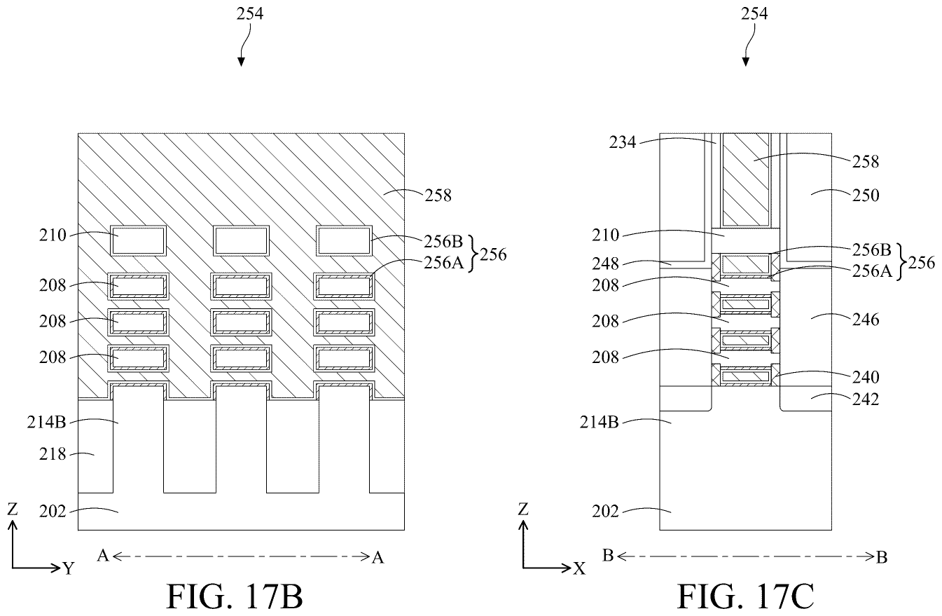

At operation 130, the method 100 (FIG. 1A) forms a metal gate structure 254 in the gate trench 252, as shown in FIGS. 17A-17C. The metal gate structure 254 wrap around each of the channel members 208, as well as the hard masks 210, in the channel region. The inner spacers 240 separate the metal gate structure 254 from contacting the doped epitaxial features 246.

The metal gate structure 254 includes a gate dielectric layer 256 wrapping each of the channel members 208 in the channel region and a gate electrode layer 258 formed on the gate dielectric layer 256. The gate dielectric layer 256 also wraps around the hard masks 210. In some embodiments, the gate dielectric layer 256 includes one or more layers of dielectric material(s). In furtherance of some embodiments, the gate dielectric layer 256 includes an interfacial layer 256A and a high-k dielectric layer 256B formed on the interfacial layer 256A. The interfacial layer 256A may be formed by an oxidization process that oxidizes exposed semiconductive surfaces of the channel members 208 and exposed semiconductive surfaces of the fin-shape base 214B. That is, the exposed dielectric surfaces of the STI feature 218 and the hard mask 210 may not be directly covered by the interfacial layer 256A. The high-k dielectric layer 256B is then deposited over the interfacial layer 256A using ALD, CVD, and/or other suitable methods. The exposed dielectric surfaces of the STI feature 218 and the hard mask 210 are in contact with the high-k dielectric layer 256B instead. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In one embodiment, the high-k dielectric layer 256B is formed using a highly conformal deposition process such as ALD in order to ensure the formation of a gate dielectric layer having a uniform thickness around each channel members.

The gate electrode layer 258 is formed on the gate dielectric layer 256 to wrap around each of the channel members 208 and the hard mask 210. The gate electrode layer 258 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAIN, TaCN, TaC, TaSiN, metal alloys, other suitable materials, and/or combinations thereof. The gate electrode layer 258 may be formed by CVD, ALD, electro-plating, or other suitable method. In certain embodiments of the present disclosure, one or more work function adjustment layers are interposed between the gate dielectric layer and the gate electrode layer. The work function adjustment layers are made of a conductive material such as a single layer of TiN, TaN, TaAIC, TiC, TaC, Co, Al, TiAl, HfTi, TiSi, TaSi or TiAIC, or a multilayer of two or more of these materials. For the n-channel FET, one or more of TaN, TaAIC, TiN, TiC, Co, TiAl, HfTi, TiSi and TaSi is used as the work function adjustment layer, and for the p-channel FET, one or more of TiAIC, Al, TiAl, TaN, TaAIC, TIN, TiC and Co is used as the work function adjustment layer. The work function adjustment layer may be formed by ALD, PVD, CVD, e-beam evaporation, or other suitable process. Further, the work function adjustment layer may be formed separately for the n-type transistors and the p-type transistors which may use different metal layers.

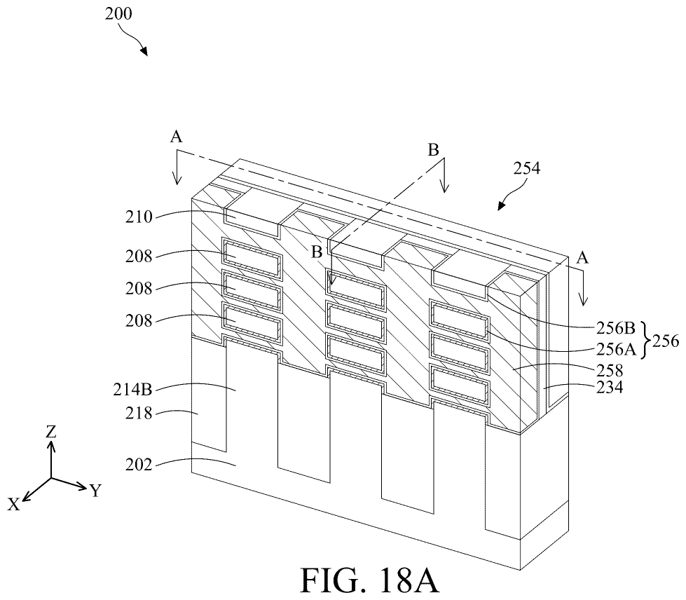

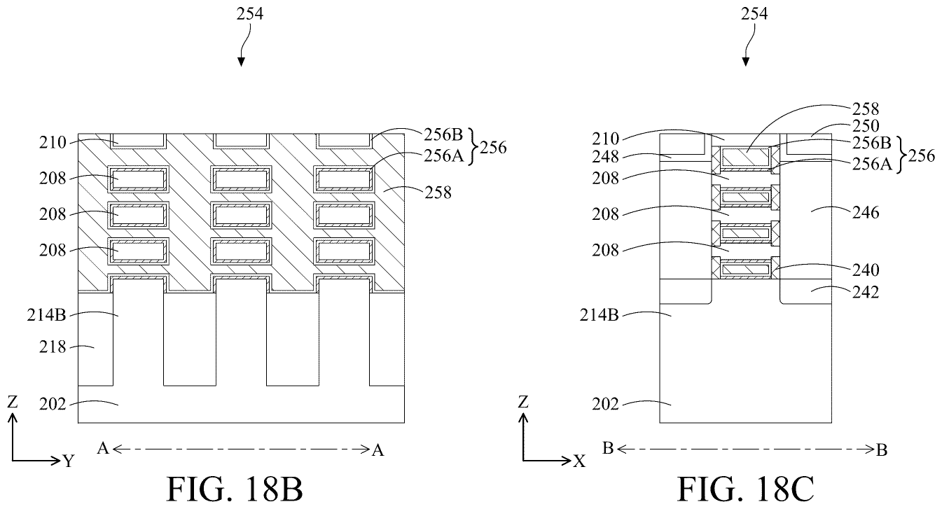

At operation 132, the method 100 (FIG. 1A) performs a planarization process, such as a CMP process, to remove excessive dielectric material and conductive material and expose the hard masks 210, as shown in FIGS. 18A-18C. Conventionally, it is hard to control the height reduction amount during a planarization process without having a planarization stop layer in the channel region. To leave sufficient process margin, the remaining metal gate height may often need to be larger than what is actually needed, which increases parasitic capacitance and reduces circuit speed. Further, a conventional planarization process applied on a large surface, such as a long metal gate structure extending across multiple fins 214 along the Y-direction, may lead to a curvy recessed top surface. As a comparison, by having the hard masks 210 function as a planarization stop layer, the metal gate height can be easily controlled with a more uniform flat top surface. The planarization process removes a top portion of the hard masks 210 and exposes the dielectric material of the hard masks 210 and the high-k dielectric layer 256B on the recessed top surface of the device 200. In the depicted embodiment, the previously larger thickness of the hard mask 210 may now become smaller than the thickness of the channel members 208 at the conclusion of operation 132. Alternatively, the thickness of the hard mask 210 may become equal to or remain larger than the thickness of the channel members 208 at the conclusion of operation 132, in accordance with some other embodiments. In some embodiments, at the conclusion of operation 132, the hard mask 210 has a thickness ranging from about 1 nm to about 18 nm.

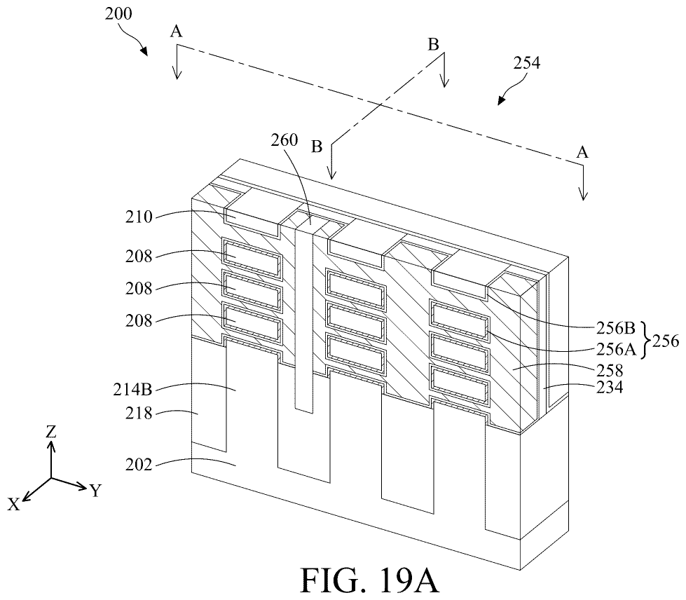

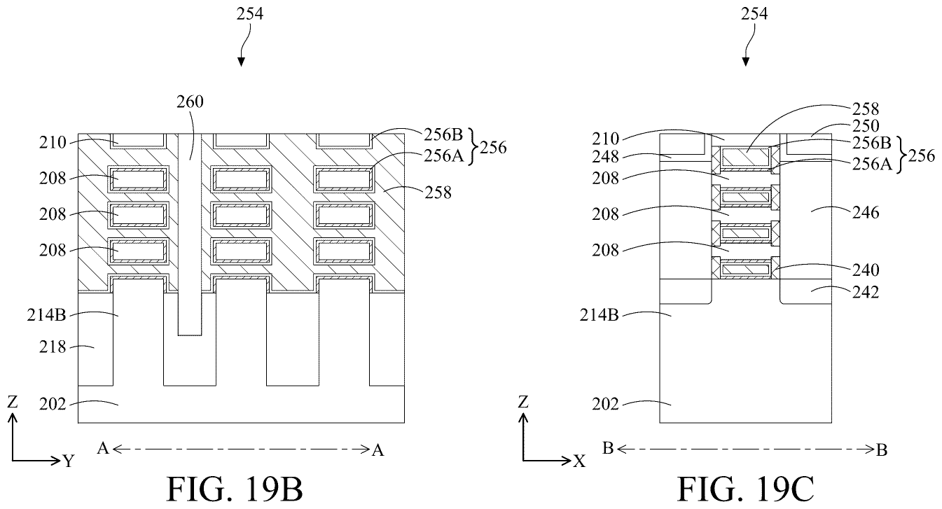

At operation 134, the method 100 (FIG. 1A) forms a dielectric feature 260 that divides the metal gate structure 254 into two isolated segments, as shown in FIGS. 19A-19C. Each of the segments of the metal gate structure 254 functions as a metal gate for the respective transistors. Since the dielectric feature 260 provides isolation between the two segments of the metal gate structure 254, it is also referred to as an isolation feature 260. To form the isolation feature 260, operation 134 may first form a trench in an etching process. The etching process may use one or more etchants or a mixture of etchants that etch the various layers in the gate electrode layer 258 and the high-k dielectric layer 256B, such as a dry etching process with an etchant having the atoms of chlorine, fluorine, bromine, oxygen, hydrogen, carbon, or a combination thereof. In the depicted embodiment, to ensure the isolation between the divided segments of the metal gate structure 254, operation 134 performs some over-etching to extend the trench into the STI feature 218. Such over-etching is carefully controlled to not expose the substrate 202. Subsequently, operation 134 fills the trench with one or more dielectric materials to form the isolation feature 260, and performs a planarization process, such as a CMP process, to planarize the top surface of the device 200. The one or more dielectric materials in the trench form the isolation feature 260. The one or more dielectric materials may be deposited using CVD, PVD, ALD, or other suitable methods.

In some embodiment, the isolation feature 260 includes one uniform layer of a dielectric material (e.g., silicon oxide or silicon nitride). In some other embodiments, the isolation feature 260 includes multiple dielectric layers. For example, due to the high aspect ratio of the trench, the deposition of the one or more dielectric materials may include multiple deposition steps. For example, a first dielectric material is deposited into the trench and etched back to form a lower portion of the isolation feature 260. The etching back process is to make sure that substantially no voids are trapped in the trench. Subsequently, a second dielectric material is deposited into the trench to form an upper portion of the isolation feature 260. The first dielectric material and the second dielectric material may be the same, such as an oxide (e.g., silicon oxide) or a nitride (e.g., silicon nitride). Alternatively, the first dielectric material and the second dielectric material may be different, such as the first dielectric material being an oxide and the second dielectric material being a nitride, or vice versa. Regardless of the first and second dielectric materials being the same or different, an interface between the first and second dielectric materials may be discernable due to the two different deposition steps.

In some other embodiments, instead of lower and upper portions, the isolation feature 260 includes an outer portion and an inner portion. The outer portion of the isolation feature 260 is formed first, such as through a conformal deposition process. Subsequently, an inner portion of the isolation feature 260 is formed, which is wrapped by the outer portion. The inner and outer portions of the isolation feature 260 may include different material compositions. For example, the outer portion of the isolation feature 260 may include an oxide (e.g., silicon oxide), and the inner portion of the isolation feature 260 may include a nitride (e.g., silicon nitride). The inner portion of the isolation feature 260 being a nitride makes the isolation feature 260 more resistible in later etching and/or planarization processes. Alternatively, since the metallic materials of the metal gate structure 254 is in contact with the outer portion of the isolation feature 260, the outer portion may be free of active chemical components such as oxygen (O). For example, the outer portion of the isolation feature 260 may include silicon nitride and is free of oxygen or oxide. The isolation feature 260 may include some oxide in the inner portion thereof in some embodiments.

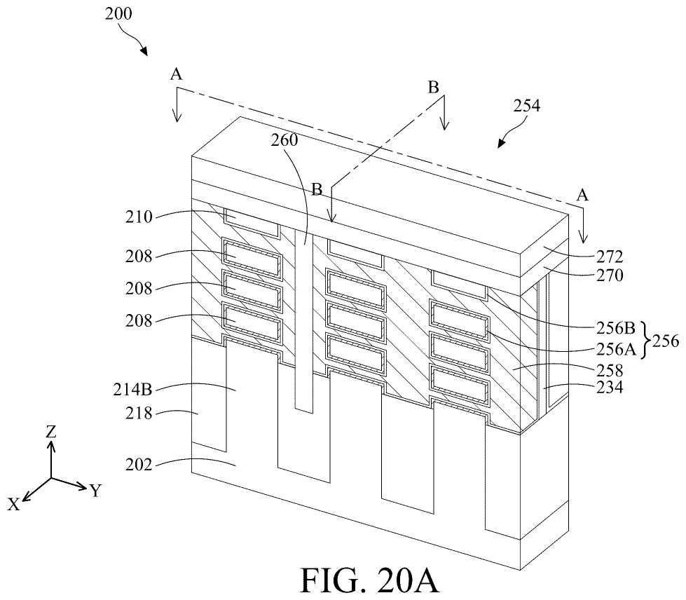

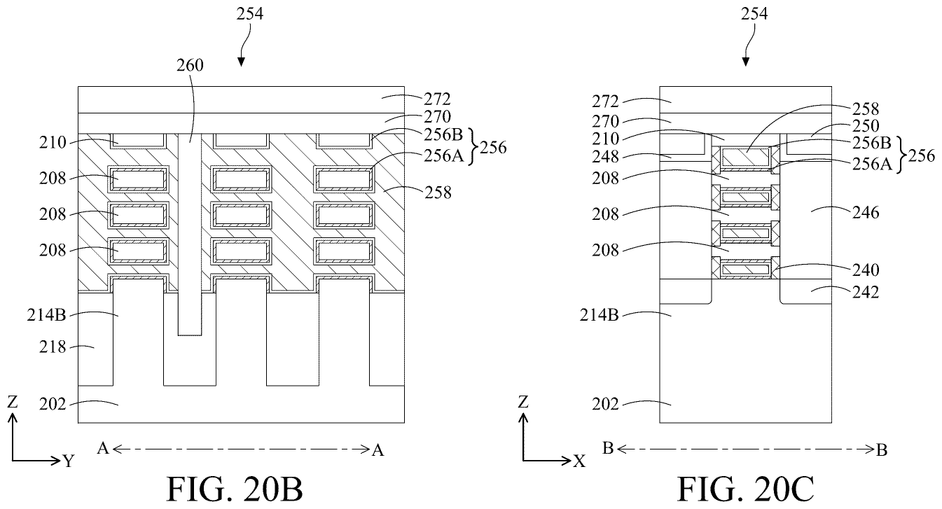

At operation 136, the method 100 (FIG. 1A) deposits an etch stop layer (ESL) 270 and a dielectric layer 272 over the ESL 270, such as shown in FIGS. 20A-20C. In some embodiments, the ESL 270 may comprise silicon nitride, silicon oxynitride, silicon nitride with oxygen (O) or carbon (C) elements, and/or other materials; and may be formed by CVD, PVD, ALD, or other suitable methods. The ESL 270 covers the exposed top surfaces of the hard masks 210 and the gate electrode layer 258. In some embodiments, the dielectric layer 272 is another ILD layer and may comprise TEOS oxide, un-doped silicate glass, or doped silicon oxide such as BPSG, FSG, PSG, BSG, and/or other suitable dielectric materials. The dielectric layer 272 may be formed by PECVD, FCVD, or other suitable methods.

At operation 138, the method 100 (FIG. 1A) forms gate plugs (or referred to as gate vias) 274 on the divided gate segments of the metal gate structure 254. The gate plugs 274 each extend through the dielectric layer 272 and the ESL 270 to land on the gate electrode layer 258. If the position of a gate plug 274 is directly above the hard mask 210, the gate plug 274 further extends through the hard mask 210 and the high-k dielectric layer 256B underneath to get in contact with the gate electrode layer 258. In the depicted embodiment, the gate plugs 274 includes a first type gate plug 274A that extends through the dielectric layer 272 and the ESL 270, and a second type gate plug 274B that extends through the dielectric layer 272, the ESL 270, as well as the hard mask 210 and the high-k dielectric layer 256B underneath the hard mask 210. The longer gate plug 274B has a bottom surface that is lower than that of the shorter gate plug 274A for about 2 nm to about 25 nm, in some embodiments. The forming of the gate plugs 274 includes forming plug holes through respective dielectric layers by an etching process and depositing conductive materials in the plug holes as the gate plugs 274. In an embodiment, the conductive materials include a barrier layer (such as TaN or TiN) and a metal fill layer (such as Al, Cu, or W). The layers in the conductive materials may be deposited using CVD, PVD, PECVD, ALD, plating, or other suitable methods.

At operation 140, the method 100 (FIG. 1A) performs further steps to complete the fabrication of the device 200. For example, the method 100 may form metal interconnects electrically connecting the source, drain, gate plugs of various transistors to form a complete IC.

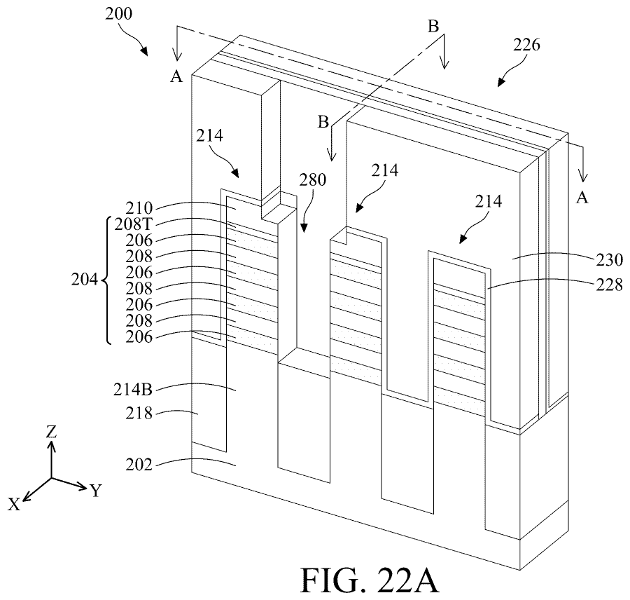

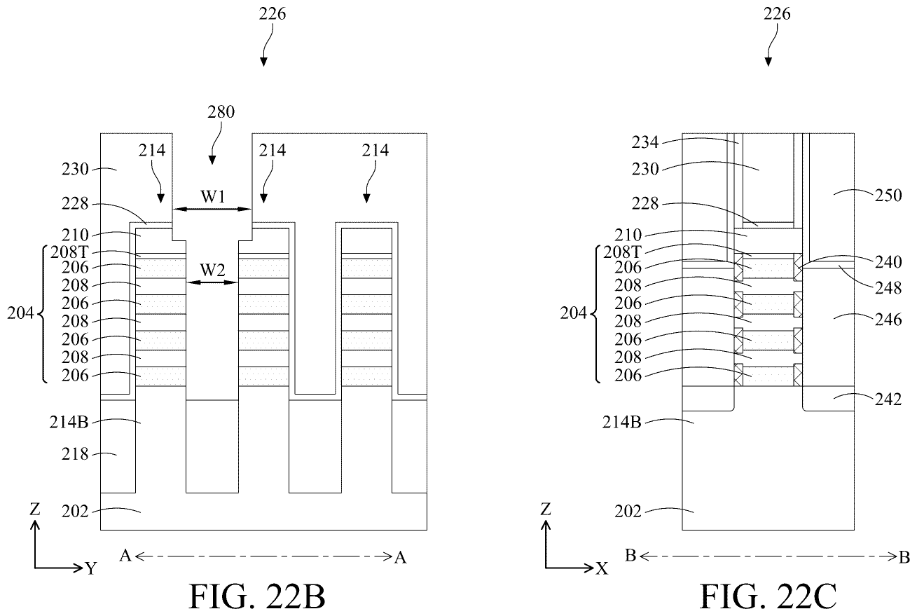

Reference is now made to FIG. 1B, which illustrates an alternative embodiment of the method 100. In the alternative embodiment of the method 100, after the forming of the CESL 248 and ILD layer 250 at operation 118, instead of proceeding to operation 124 in removing the sacrificial gate structure 226, the method 100 proceeds to operation 120 in etching the sacrificial gate structure 226 to form a trench 280, as shown in FIGS. 22A-22C. In some embodiments, operation 120 uses a lithography process that includes forming a resist layer over the device 200 (e.g., by spin coating), performing a pre-exposure baking process, performing an exposure process using a mask, performing a post-exposure baking process, and performing a developing process. After development, the developed resist layer includes a resist pattern that defines an opening with a width W1 above adjacent two fins 214. The width W1 is larger than the spacing W2 between the adjacent two fins 214. The etching process may use one or more etchants or a mixture of etchants that etch the various layers in the sacrificial gate electrode layer 230 and the sacrificial gate dielectric layer 228 through the opening defined in the developed resist layer and extend into the region between the adjacent two fins 214 with no (or minimal) etching loss occurred to the epitaxial stack 204 and the STI feature 218. Since the selective etching process is self-aligned as being confined within the region between two adjacent fins 214, operation 120 is not sensitive to the exact location of the opening with the relatively larger width W1. The resultant trench 280 has the relatively larger width W1 in its top portion and the relatively smaller width W2 in its bottom portion. The trench 280 exposes the top surface of the STI feature 218 but does not extend into the STI feature 218. Due to the limited etching contrast, the hard masks 210 may suffer from some etching loss, such that a corner portion of the hard masks 210 may be recessed, as shown in the depicted embodiment.

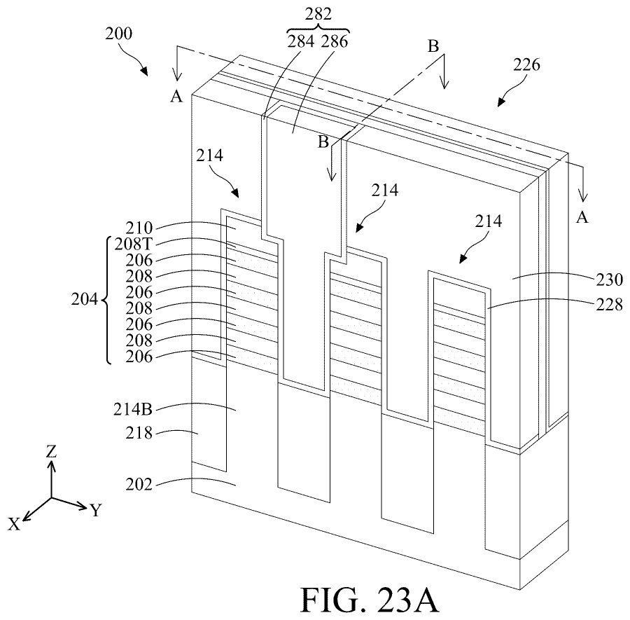

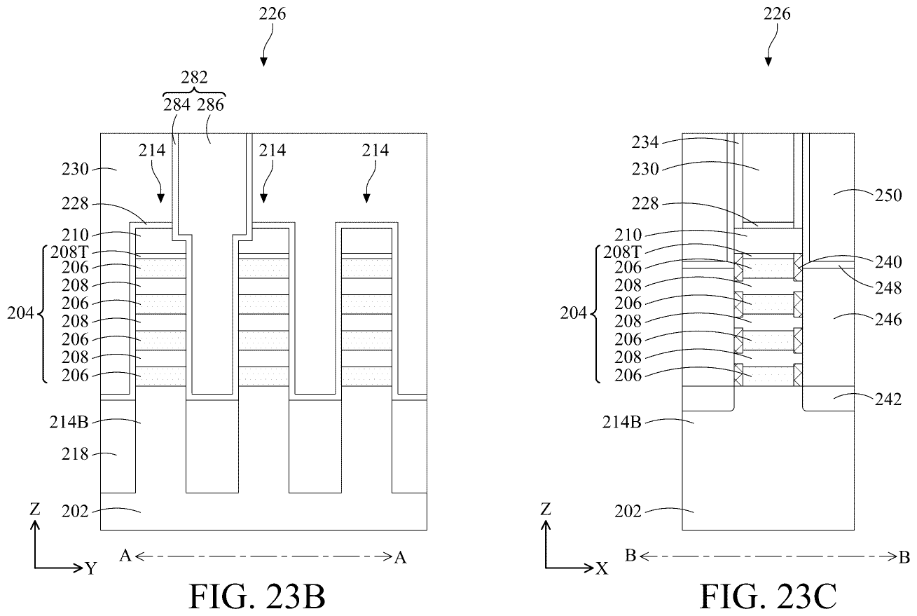

At operation 122, the method 100 (FIG. 1B) fills the trench 280 with one or more dielectric materials to form an isolation feature 282, as shown in FIGS. 23A-23C. The one or more dielectric materials of the isolation feature 282 and the deposition thereof may be substantially similar to the isolation feature 260 as discussed above, such as through a multi-step deposition process in forming lower and upper portions of the isolation feature 282 or outer and inner portions of the isolation feature 282. In the depicted embodiment as shown in FIG. 23B, the one or more dielectric materials of the isolation feature 282 includes a dielectric liner 284 deposited on sidewalls and bottom surface of the trench 280 and a dielectric inner layer 286 filling the remaining opening of the trench 280. The dielectric liner 284 may include some oxide, SiN, SiCN, SiOC, SiOCN, or other suitable dielectric material. The dielectric inner layer 286 may include SiN, SiCN, SiOC, SiOCN, or other suitable dielectric material. In one embodiment, the dielectric liner 284 may include silicon nitride and is free of oxygen or oxide to avoid oxidization of the metallic layers in the to-be-formed metal gate structure.

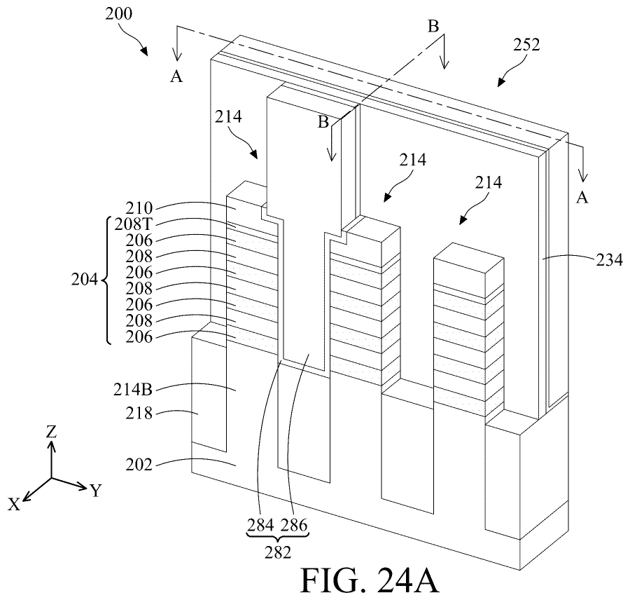

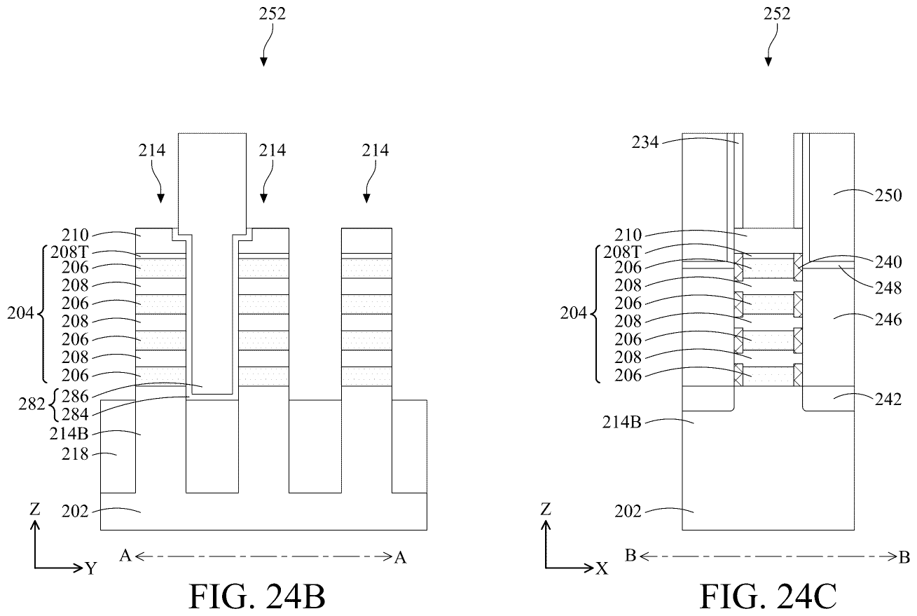

At operation 124, the method 100 (FIG. 1B) removes the sacrificial gate structure 226 to form a gate trench 252 in an etch process, as shown in FIGS. 24A-24C. The removal of the sacrificial gate structure 226 may include one or more etching processes that are selective to the material of the sacrificial gate structure 226. For example, the removal of the sacrificial gate structure 226 may be performed using as a selective wet etch, a selective dry etch, or a combination thereof that is selective to the sacrificial gate structure 226. In one embodiment, the etching process is a reactive-ion etching (RIE). After the removal of the sacrificial gate structure 226, in the channel region sidewalls of the channel layers 208 and the sacrificial layers 206, as well as the hard masks 210, are exposed in the gate trench 252. The exposed portion of the dielectric liner 284 may also be removed, such that a top portion of the dielectric inner layer 286 above the hard mask 210 is exposed. In some embodiments that an anisotropic dry etching is applied, the hard masks 210 protect the underneath epitaxial layers 206 and 208 from etching loss. A thickness of the hard masks 210 may reduce about 5% to about 20% at the conclusion of operation 124 due to limited etching contrast.

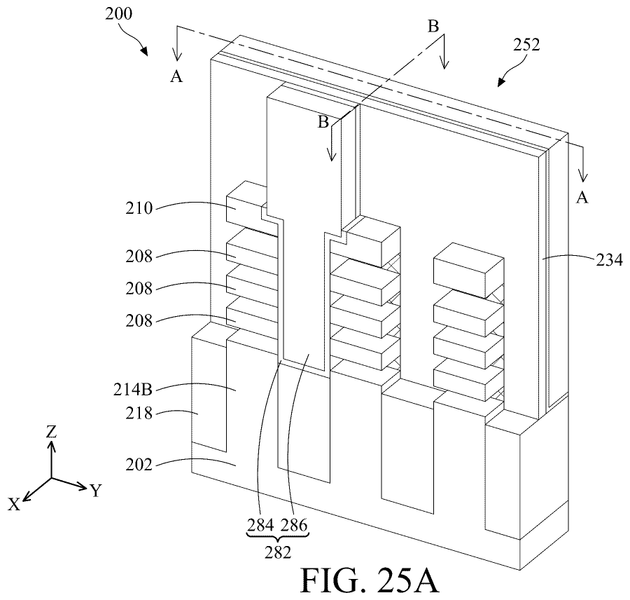

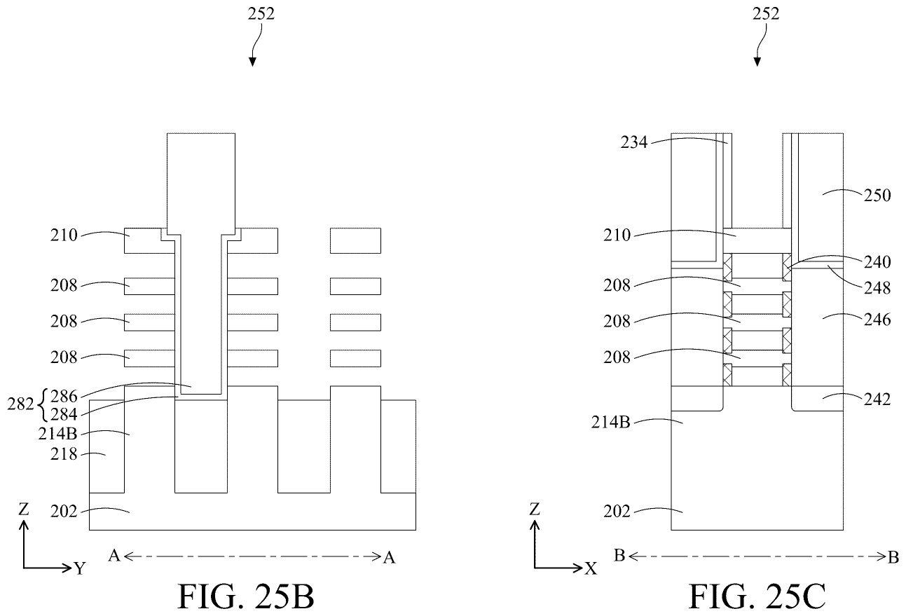

At operation 126, the method 100 (FIG. 1B) selectively removes the sacrificial layers 206 from the gate trench 252 in an etch process, as shown in FIG. 25A-25C. The selective removal of the sacrificial layers 206 releases the channel members 208. The selective removal of the sacrificial layers 206 also leaves behind gaps between channel members 208. The dielectric liner 284 of the isolation feature 282 are also exposed in the gaps. The selective removal of the sacrificial layers 206 may be implemented by selective dry etch, selective wet etch, or other selective etch processes. The selective removal of the sacrificial layers 206 also removes the top sacrificial layer 208T.

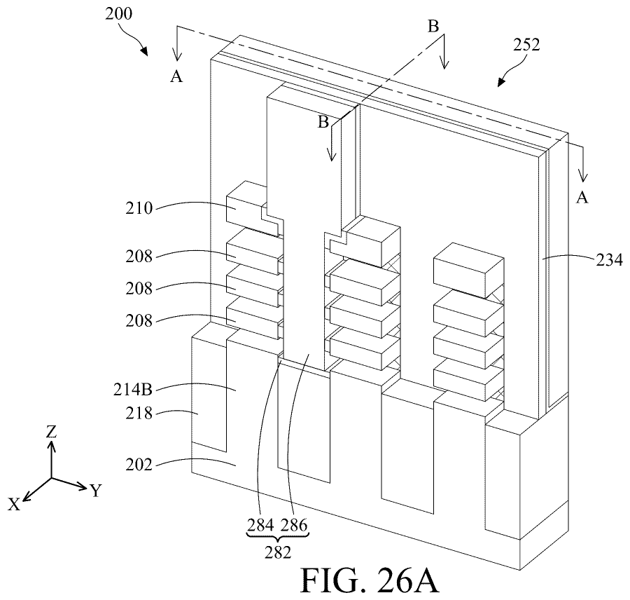

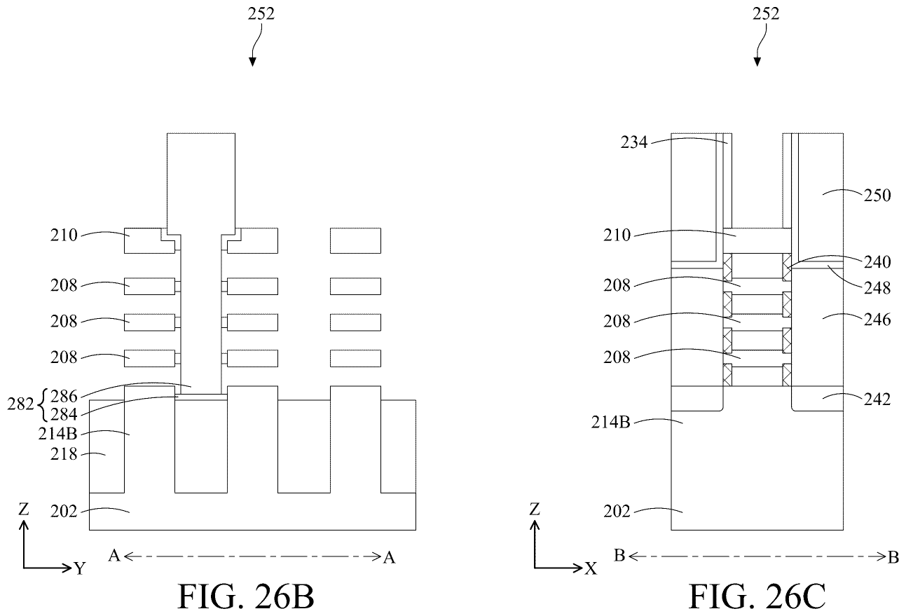

At operation 128, the method 100 (FIG. 1B) trims the exposed dielectric liner 284 of the CMG feature 282 to expand the gaps between adjacent channel members 208, as shown in FIGS. 26A-26C. The trimming of the dielectric liner 284 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). The trimming of the dielectric liner 284 exposes sidewalls of the dielectric inner layer 286 in the gaps between adjacent channel members 208. The exposed sidewalls of the dielectric inner layer 286 may have a vertical length of about 0 nm to about 5 nm between adjacent remaining segments of the dielectric liner 284. A first portion of the dielectric liner 284 is stacked laterally between the channel members 208 and the dielectric inner layer 286, as the etchant may be difficult to reach this portion of the dielectric liner 284. Similarly, a second portion of the dielectric liner 284 is stacked vertically between the STI feature 218 and the dielectric inner layer 286, and a third portion of the dielectric liner 284 is staked laterally between the hard mask 210 and the dielectric inner layer 286.

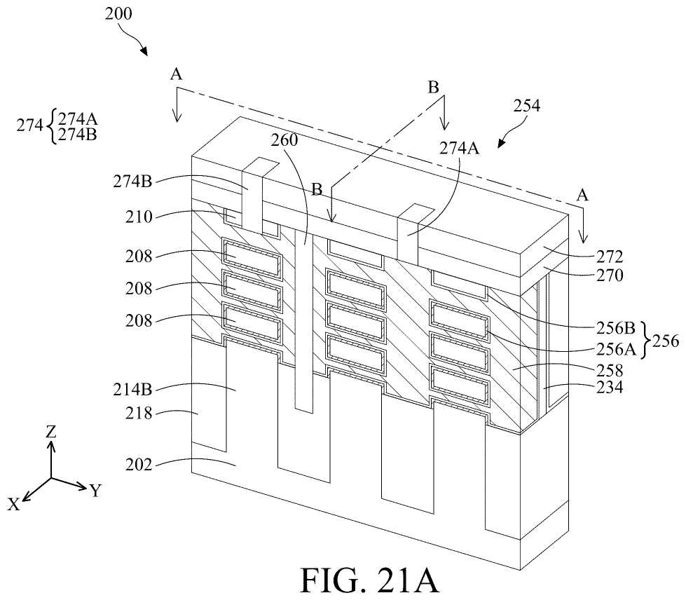

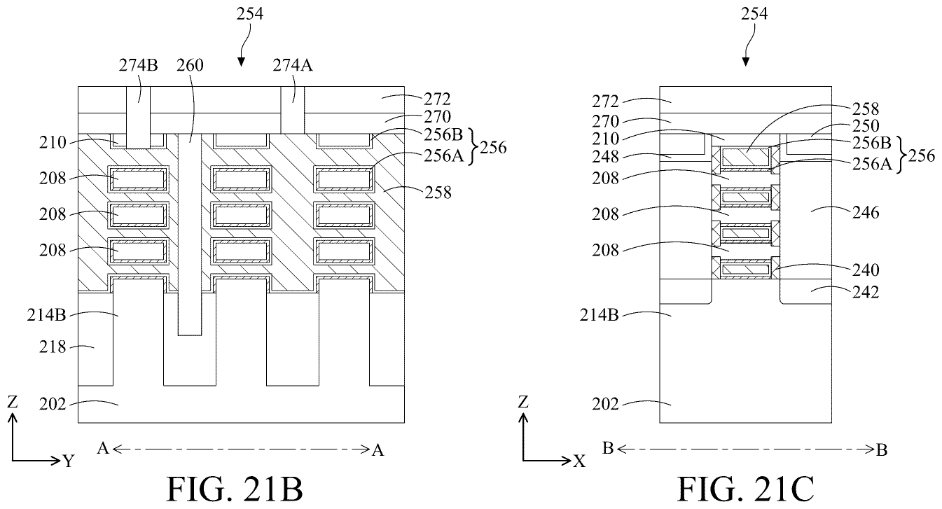

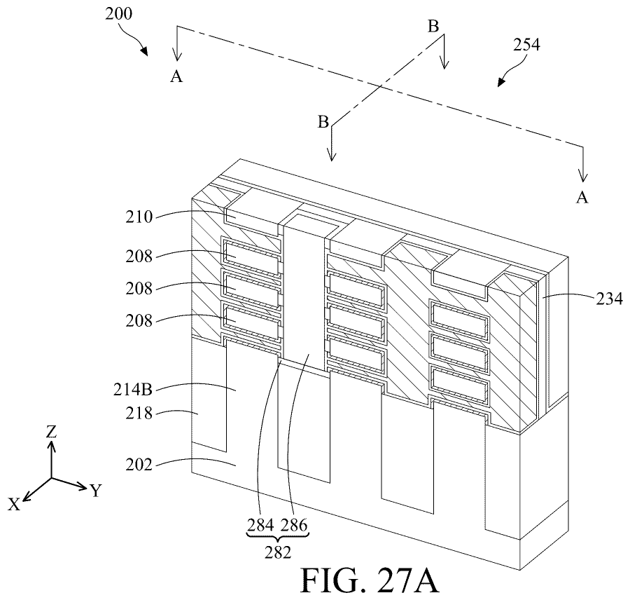

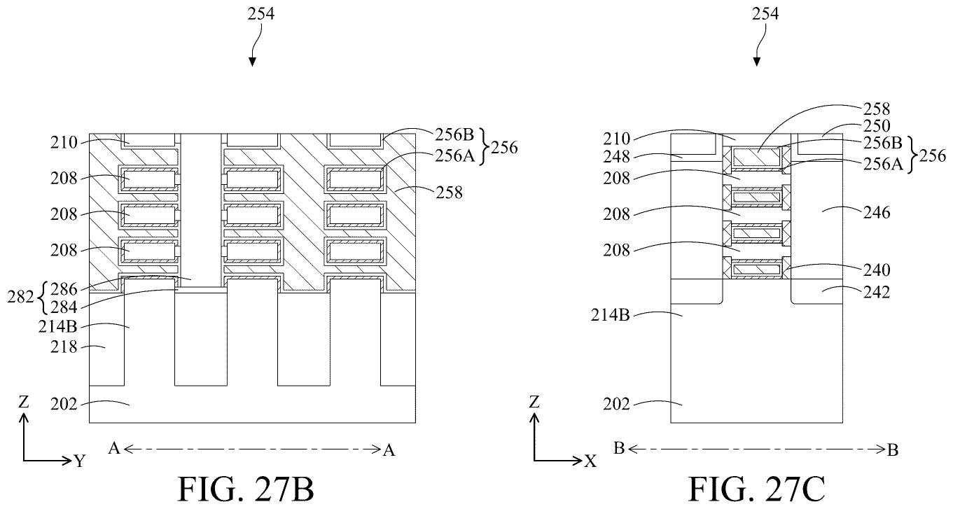

At operation 130, the method 100 (FIG. 1B) forms a metal gate structure 254 in the gate trench 252, as shown in FIGS. 27A-27C. The metal gate structure 254 wrap around each of the channel members 208, as well as the hard masks 210, in the channel region. The inner spacers 240 separate the metal gate structure 254 from contacting the doped epitaxial features 246. The interfacial layer 256A and the high-k dielectric layer 256B fill the space between the channel members 208 and the dielectric inner layer 286, which is spared from the trimming process at operation 128. The isolation feature 282 divides the metal gate structure 254 into two isolated segments. Unlike the isolation feature 260 (FIGS. 21A and 21B), the isolation feature 282 as depicted in FIG. 27B is not partially embedded in the STI feature 218.

At operation 132, the method 100 (FIG. 1B) performs a planarization process, such as a CMP process, to remove excessive dielectric material and conductive material and expose the hard masks 210, as also shown in FIGS. 27A-27C. By having the hard masks 210 functions as a planarization stop layer, the metal gate height can be easily controlled with a more uniform flat top surface. The planarization process removes a top portion of the hard masks 210 and exposes the dielectric material of the hard masks 210, as well as the high-k dielectric layer 256B and the isolation feature 282. In the depicted embodiment, the top portion of the isolation feature 282 with the larger width W1 is completely removed by the planarization process, and the bottom portion of the isolation feature 282 with the smaller width W2 remains.

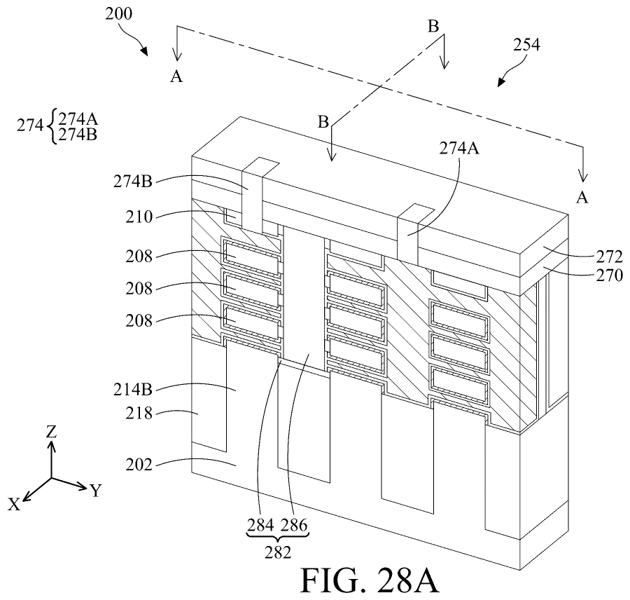

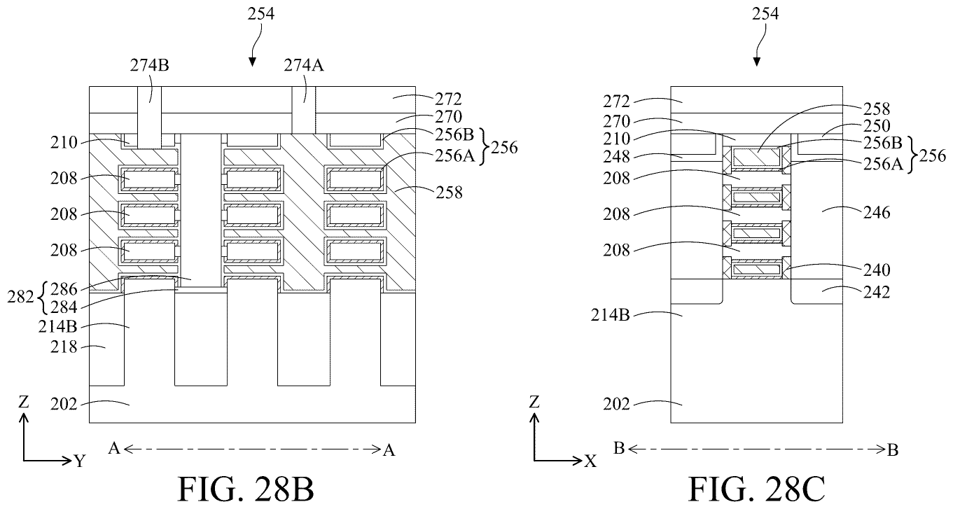

After operation 132, the alternative embodiment of the method 100 proceeds to operation 136 (FIG. 1A), in which an etch stop layer (ESL) 270 and a dielectric layer 272 are deposited, and subsequently operation 138 (FIG. 1A), in which gate plugs 274 are formed, such as shown in FIGS. 28A-28C. Also at operation 140, the method 100 (FIG. 1A) performs further steps to complete the fabrication of the device 200. For example, the method 100 may form metal interconnects electrically connecting the source, drain, gate plugs of various transistors to form a complete IC.

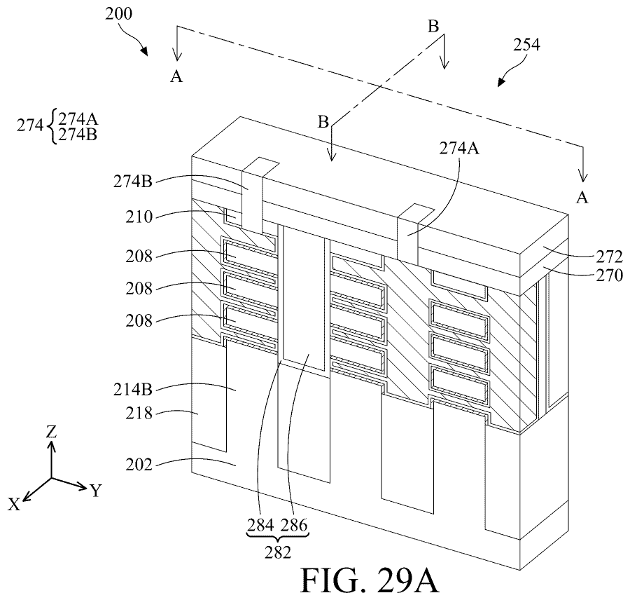

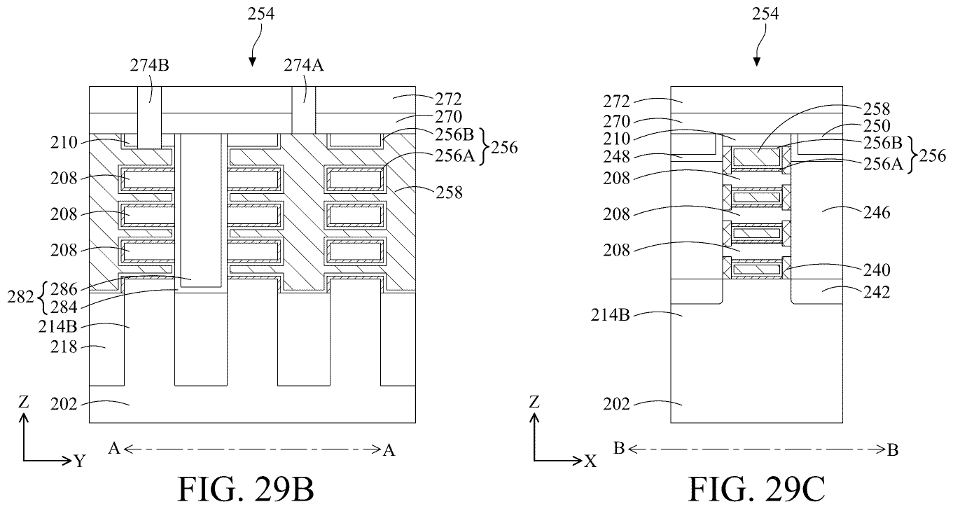

FIGS. 29A-29C illustrate an alternative embodiment of the device 200 at the conclusion of operation 138, in which the dielectric liner 284 is not trimmed (e.g., operation 128 is skipped). Therefore, the dielectric liner 284 separates the dielectric inner layer 286 from contacting the high-k dielectric layer 256B. The interfacial layer 256A and the high-k dielectric layer 256B are also not positioned laterally between the channel members and the isolation feature 282.

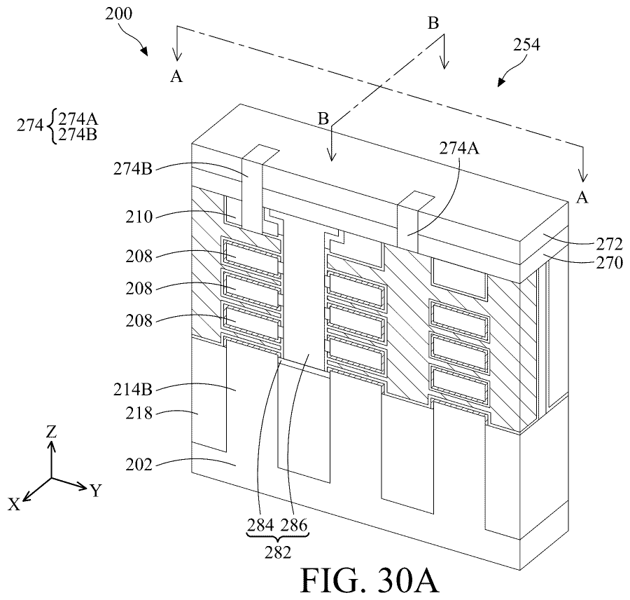

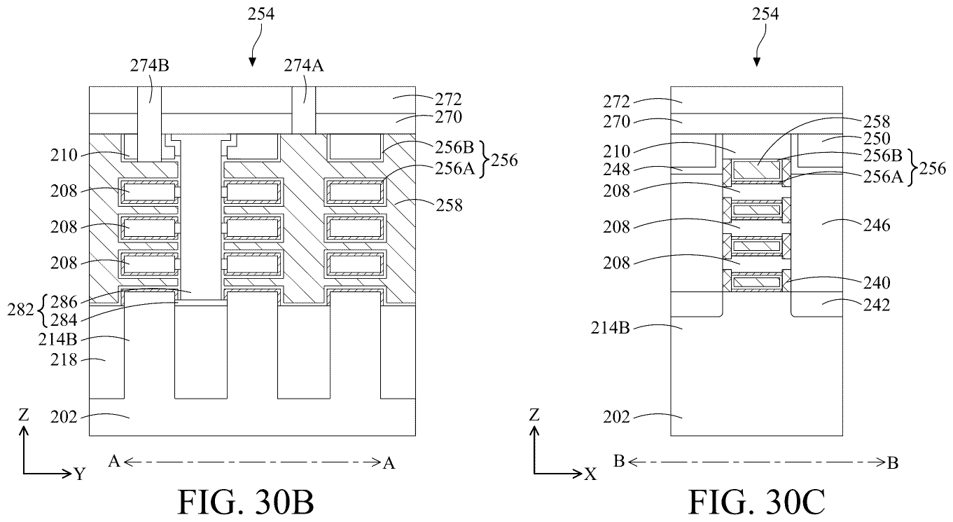

FIGS. 30A-30C illustrate another alternative embodiment of the device 200 at the conclusion of operation 138, in which a top portion of the isolation feature 282 remains by controlling the amount of metal gate height reduction in the planarization process at operation 132. Therefore, the isolation feature 282 has a top portion with a larger width W1 and a bottom portion with a smaller width W2.

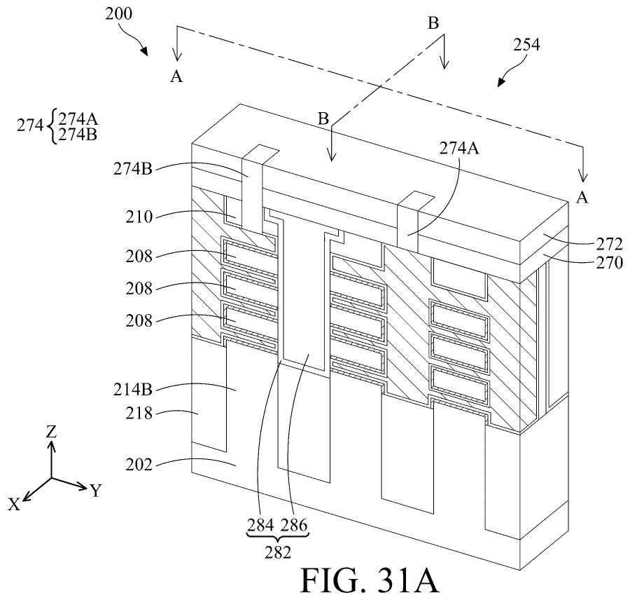

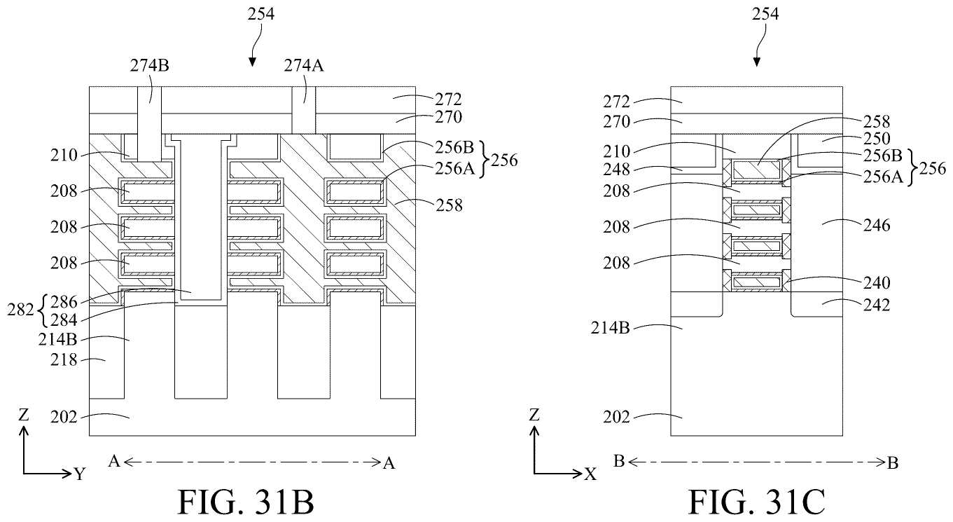

FIGS. 31A-31C illustrate another alternative embodiment of the device 200 at the conclusion of operation 138, in which the dielectric liner 284 is not trimmed (e.g., operation 128 is skipped) and a top portion of the isolation feature 282 remains. Therefore, the dielectric liner 284 separates the dielectric inner layer 286 from contacting the high-k dielectric layer 256B. The interfacial layer 256A and the high-k dielectric layer 256B are also not positioned laterally between the channel members and the isolation feature 282. Further, the isolation feature 282 has a top portion with a larger width W1 and a bottom portion with a smaller width W2.

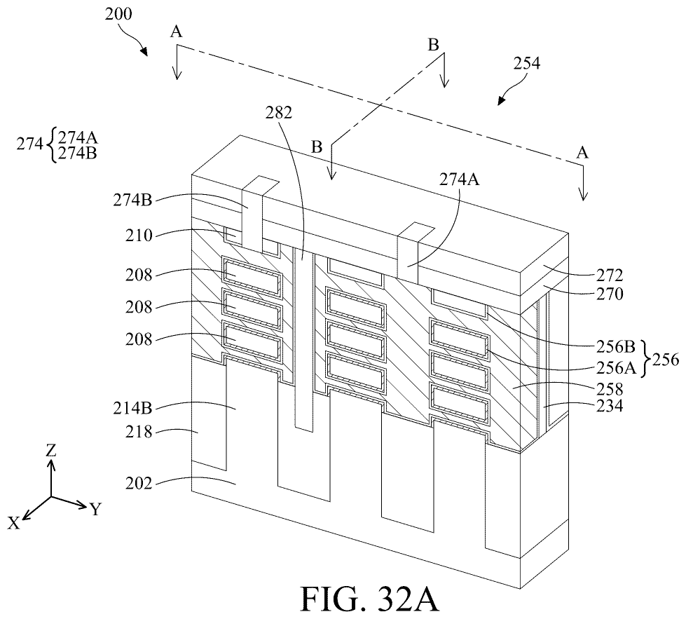

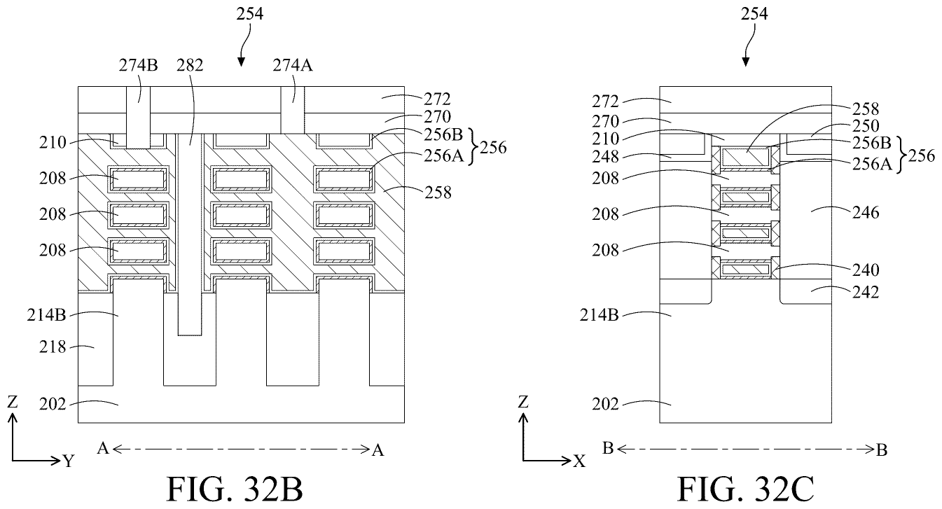

FIGS. 32A-32C illustrate another alternative embodiment of the device 200, in which the isolation feature 282 does not expand the whole lateral distance between the channel members 208. That is, the isolation feature 282 is spaced apart from the channel members 208 with the high-k dielectric layer 256B and the gate electrode layer 258 therebetween. The resultant structure is similar to the embodiment depicted in FIGS. 21A-21C. One of the differences is that the high-k dielectric layer 256B is deposited on sidewalls of the isolation feature 282 due to the formation of the metal gate structure 254 after the formation of the isolation feature 282. In the depicted embodiment, the isolation feature 282 is also partially embedded in the STI feature 218.

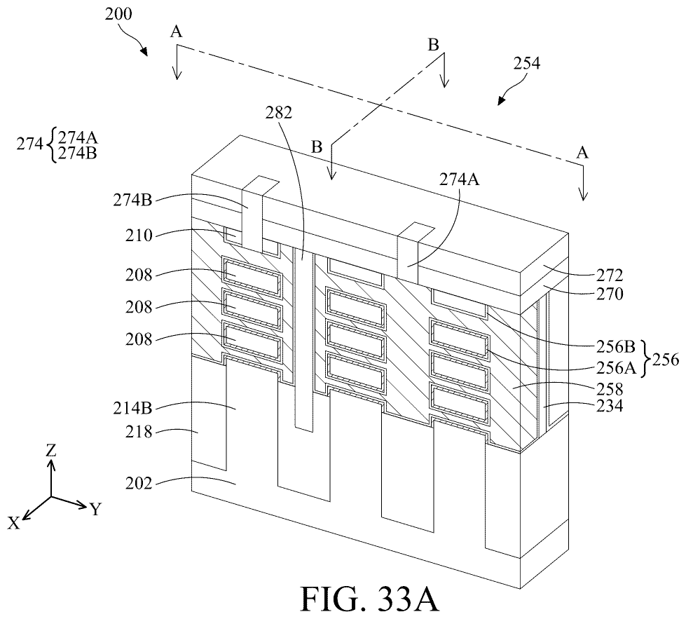

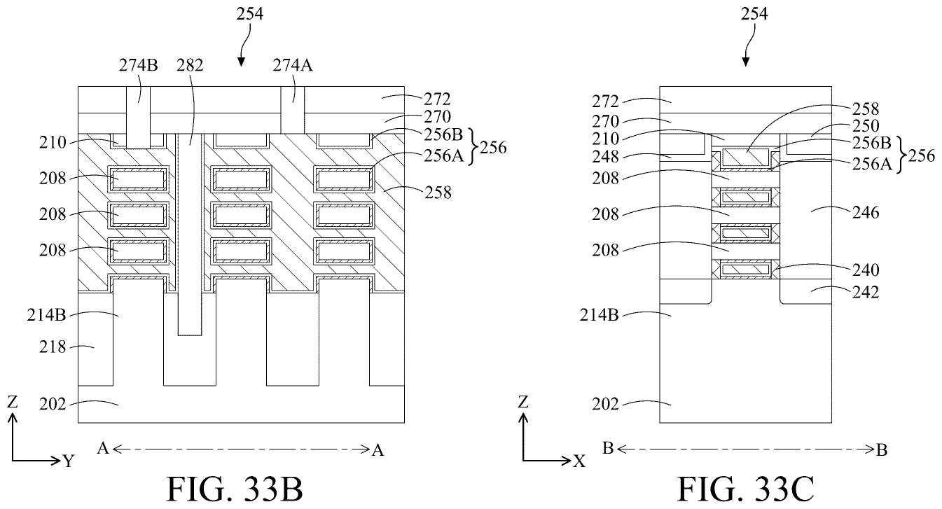

FIGS. 33A-33C illustrate another alternative embodiment of the device 200, in which a portion of the high-k dielectric layer 256B is interposed between the topmost inner spacer 240 and the bottom surface of the hard mask 210 (FIG. 33C). This may be due to a high etch selective at operation 114 such that the top sacrificial layer 208T is not recessed in the X-direction (as compared to FIG. 10C) and the metal gate structure 254 later takes the space reversed by the top sacrificial layer 208T. In such an embodiment, the high-k dielectric layer 256B may be in contact with the CESL 248, as depicted in FIG. 33C. The high-k dielectric layer 256B being in contact with the CESL 248 and separating the topmost inner spacer 240 from the bottom surface of the hard mask 210 may also occur to the other embodiments as depicted in FIGS. 21A-21C and FIGS. 28A-32C.

Although not intended to be limiting, embodiments of the present disclosure provide one or more of the following advantages. For example, embodiments of the present disclosure form a dielectric structure suspended above vertically stacked channel members in a channel region of a multi-gate transistor. This advantageously improves uniformity of the channel member thickness and the metal gate height. Further, embodiments of the present disclosure can be readily integrated into existing semiconductor manufacturing processes.

In one exemplary aspect, the present disclosure is directed to a method. The method includes forming a stack over a substrate, the stack comprising a plurality of channel layers interleaved by a plurality of sacrificial layers, depositing a dielectric structure over the stack, patterning the dielectric structure and the stack to form a fin-shape structure, the fin-shape structure comprising a channel region and a source/drain region, forming a dummy gate stack over the channel region of the fin-shape structure, depositing gate spacers on sidewalls of the dummy gate stack, recessing the fin-shape structure in the source/drain region to form a source/drain trench that exposes sidewalls of the channel layers and the sacrificial layers, partially recessing the sacrificial layers to form a plurality of inner spacer cavities, forming a plurality of inner spacers in the inner spacer cavities, forming an epitaxial feature in the source/drain trench, the epitaxial feature abutting the channel layers, after the forming of the epitaxial feature, removing the dummy gate stack to form a gate trench, releasing the channel layers in the channel region as a plurality of channel members by removing the sacrificial layers, the dielectric structure being suspended above the channel layers in the channel region, and forming a metal gate structure in the gate trench, the metal gate structure wrapping around each of the channel members and the dielectric structure. In some embodiments, the method further includes recessing the metal gate structure to expose the dielectric structure. In some embodiments, the method further includes forming a gate plug extending through the dielectric structure and in contact with the metal gate structure. In some embodiments, after the releasing of the channel layers, the dielectric structure and a topmost one of the channel members have a same width. In some embodiments, the metal gate structure is in contact with the dielectric structure. In some embodiments, the method further includes depositing a hard mask layer above the dielectric structure, patterning the hard mask layer, wherein the fin-shape structure includes the hard mask layer, depositing an isolation feature on sidewalls of the stack, the dielectric structure, and the hard mask layer, selectively removing the hard mask layer to expose the dielectric structure, and recessing the isolation feature. In some embodiments, the method further includes forming an isolation feature. The isolation feature separates the metal gate structure into two isolated segments. In some embodiments, the isolation feature includes a bottom portion and a top portion with a discernable interface therebetween. In some embodiments, the isolation feature includes an outer layer of a first dielectric material and an inner layer of a second dielectric material that is different from the first dielectric material.

In another exemplary aspect, the present disclosure is directed to a method. The method includes forming a plurality of semiconductor nanostructures vertically stacked above a substrate, forming a dielectric structure suspended above a topmost one of the semiconductor nanostructures, forming a plurality of inner spacers interleaving the semiconductor nanostructures, forming an epitaxial feature abutting the semiconductor nanostructures, and forming a gate structure wrapping around each of the semiconductor nanostructures and the dielectric structure. In some embodiments, the method further includes planarizing the gate structure to expose the dielectric structure, depositing an interlayer dielectric layer over the dielectric structure, and forming a gate plug extending through the interlayer dielectric layer and the dielectric structure. In some embodiments, the gate structure includes an interfacial layer, a high-k dielectric layer, and a gate electrode layer. The interfacial layer is in contact with the semiconductor nanostructures. The high-k dielectric layer is in contact with the dielectric structure. In some embodiments, the method further includes depositing a dielectric layer on a top surface of the epitaxial feature. The gate structure is in contact with the dielectric layer. In some embodiments, the method further includes forming an isolation feature separating the gate structure into two isolated segments. The isolation feature is a bi-layer structure including a first dielectric layer and a second dielectric layer. The first dielectric layer and the second dielectric layer include different material compositions.

In another exemplary aspect, the present disclosure is directed to a semiconductor device. The semiconductor device includes a plurality of semiconductor nanostructures disposed over a substrate, a dielectric structure above a topmost one of the semiconductor nanostructures, a plurality of inner spacers interleaving the semiconductor nanostructures, a metal gate structure wrapping around each of the semiconductor nanostructures, a bottom surface of the dielectric structure being below a top surface of the metal gate structure, gate spacers disposed on sidewalls of the metal gate structure, and an epitaxial feature abutting the semiconductor nanostructures. In some embodiments, the top surface of the metal gate structure and a top surface of the dielectric structure are coplanar. In some embodiments, the semiconductor device further includes a gate plug extending through the dielectric structure and in contact with the metal gate structure. In some embodiments, the metal gate structure is in contact with sidewalls and the bottom surface of the dielectric structure. In some embodiments, the semiconductor nanostructures are first semiconductor nanostructures and the metal gate structure is a first metal gate structure, the semiconductor device further includes a plurality of second semiconductor nanostructures, a second metal gate structure wrapping around each of the second semiconductor nanostructures, and an isolation feature separating the first metal gate structure from the second metal gate structure. In some embodiments, the isolation feature includes a first dielectric layer and a second dielectric layer. A portion of the first dielectric layer is under the second dielectric layer. The first and second dielectric layers include different material compositions.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
an isolation feature disposed on a substrate;
a fin-shape base protruding from the substrate and through the isolation feature, a top surface of the isolation feature intersecting a sidewall of the fin-shape base;
a plurality of nanostructures disposed over a top surface of the fin-shape base;
a dielectric structure disposed over a topmost one of the nanostructures;
a gate structure wrapping around at least one of the nanostructures, the gate structure including a gate dielectric layer and a gate electrode over the gate dielectric layer, the gate electrode comprising a titanium-containing material, the gate dielectric layer interfacing with a bottom surface of the dielectric structure, wherein the bottom surface of the dielectric structure is below a top surface of the gate structure;
a gate spacer extending along a sidewall of the gate structure, a dielectric constant of the gate dielectric layer being greater than a dielectric constant of the gate spacer; and
an epitaxial feature abutting the nanostructures.

2. The semiconductor device of claim 1, further comprising:
a dielectric layer interfacing with a top surface of the epitaxial feature and interfacing with a sidewall of the dielectric structure.

3. The semiconductor device of claim 1, wherein a top surface of the dielectric structure is coplanar with the top surface of the gate structure.

4. The semiconductor device of claim 1, wherein the gate dielectric layer includes an interfacial layer and a high-k dielectric layer over the interfacial layer, the interfacial layer interfaces with the at least one of the nanostructures, and the high-k dielectric layer interfaces with the bottom surface of the dielectric structure.

5. The semiconductor device of claim 1, wherein the dielectric structure and the topmost one of the nanostructures have a same width.

6. The semiconductor device of claim 1, further comprising:
a plurality of inner spacers interleaving the nanostructures and separating the epitaxial feature from the gate structure.

7. The semiconductor device of claim 6, wherein a topmost one of the inner spacers interfaces with the bottom surface of the dielectric structure.

8. The semiconductor device of claim 1, further comprising:
a gate plug extending through the dielectric structure and the gate dielectric layer and interfacing with the gate electrode.

9. The semiconductor device of claim 1, further comprising:
a gate-cut feature dividing the gate structure into two segments, wherein a bottom surface of the gate-cut feature is below the top surface of the isolation feature.

10. The semiconductor device of claim 9, wherein the gate-cut feature is a bi-layer structure including a first dielectric layer and a second dielectric layer, and wherein the first dielectric layer and the second dielectric layer include different material compositions.

11. A semiconductor device, comprising:
an active region extending lengthwise in a first direction, a channel region of the active region including a plurality of nanostructures vertically stacked, a source/drain region of the active region including an epitaxial feature abutting the nanostructures;
a metal gate structure across the channel region and extending lengthwise in a second direction different from the first direction, the metal gate structure wrapping around at least one of the nanostructures, the metal gate structure comprising a titanium-containing material;
a dielectric structure above a topmost one of the nanostructures, a bottom surface of the dielectric structure being below a top surface of the metal gate structure; and
a gate spacer disposed on a sidewall of the metal gate structure.

12. The semiconductor device of claim 11, wherein the top surface of the metal gate structure and a top surface of the dielectric structure are coplanar.

13. The semiconductor device of claim 11, further comprising:
a gate plug extending through the dielectric structure and interfacing with the metal gate structure.

14. The semiconductor device of claim 11, wherein the metal gate structure interfaces with sidewalls and the bottom surface of the dielectric structure.

15. The semiconductor device of claim 11, wherein the nanostructures are first nanostructures and the metal gate structure is a first metal gate structure, the semiconductor device further comprising:
a second active region extending lengthwise in the first direction, a channel region of the second active region including a plurality of second nanostructures vertically stacked;
a second metal gate structure wrapping around at least one of the second nanostructures; and
an isolation feature separating the first metal gate structure from the second metal gate structure.

16. The semiconductor device of claim 15, wherein the isolation feature includes a first dielectric layer and a second dielectric layer, a portion of the first dielectric layer is under the second dielectric layer, and the first and second dielectric layers include different material compositions.

17. A method, comprising:
forming a stack over a substrate, the stack comprising a plurality of channel layers interleaved by a plurality of sacrificial layers;
depositing a dielectric structure over the stack;
patterning the dielectric structure and the stack to form a fin-shape structure, the fin-shape structure comprising a channel region and a source/drain region;
forming a dummy gate stack over the channel region of the fin-shape structure;
depositing gate spacers on sidewalls of the dummy gate stack;
recessing the fin-shape structure in the source/drain region to form a source/drain trench that exposes sidewalls of the channel layers and the sacrificial layers;
forming an epitaxial feature in the source/drain trench, the epitaxial feature abutting the channel layers;
after the forming of the epitaxial feature, removing the dummy gate stack to form a gate trench;
releasing the channel layers in the channel region as a plurality of channel members by removing the sacrificial layers; and
forming a metal gate structure in the gate trench, the metal gate structure wrapping around at least one of the channel members and wrapping around the dielectric structure.

18. The method of claim 17, further comprising:
partially recessing the sacrificial layers to form a plurality of inner spacer cavities; and
forming a plurality of inner spacers in the inner spacer cavities, wherein a topmost one of the inner spacers interfaces with a bottom surface of the dielectric structure.

19. The method of claim 17, further comprising:
recessing the metal gate structure to expose the dielectric structure.

20. The method of claim 17, further comprising:
forming a gate plug extending through the dielectric structure and interfacing with the metal gate structure.
